(19) United States
(12) Patent Application Publication
(10) Pub. No.: US 2014/0231624 A1
(43) Pub. Date: Aug. 21, 2014

(54) SEMICONDUCTOR INTEGRATED CIRCUIT AND IMAGING DEVICE

(71) Applicant: Sony Corporation, Tokyo (JP)

(72) Inventors: Tatsuo Shimizu, Chiba (JP); Seiji Wada, Kanagawa (JP)

(73) Assignee: Sony Corporation, Tokyo (JP)

(21) Appl. No.: 14/179,943

(22) Filed: Feb. 13, 2014

(30) Foreign Application Priority Data
Feb. 20, 2013 (JP) 2013-031278

(51) Int. Cl. H03K 17/04; H01L 27/146

(52) U.S. Cl. CPC H03K 17/0406; H01L 27/14643
USPC 250/208.1; 327/374

(57) ABSTRACT

There is provided a semiconductor integrated circuit including at least one MOS transistor a source or drain of which is connected an output terminal, and a driver circuit configured to drive a back gate or a well of the MOS transistor in a manner that voltage swing is in a same phase as the output terminal.

### CROSS REFERENCE TO RELATED APPLICATIONS

This application claims the benefit of Japanese Priority Patent Application JP 2013-031278 filed Feb. 20, 2013, the entire contents of which are incorporated herein by reference.

### BACKGROUND

The present disclosure relates to a semiconductor integrated circuit and an imaging device.

Wired high-speed serial interfaces of over several Gbps operation, such as a high-definition multimedia interface (HDMI) that can transmit full high definition images without compression and a USB 3.0 that can transmit large digital data in a short time, have become common in the consumer field. It is expected that images will have even higher resolution in the future, such as 4K or super high definition, and further acceleration in transmission rate in accordance with higher resolution of images is demanded.

Also in the medical equipment field, the number of signals to be handled is increasing more and more in accordance with higher resolution images and 3D images for surgical microscopes for example. Since no delay is permitted from shooting of an image to display the image in a medical examination or surgery, data need to be transferred without compression and acceleration in transmission rate is expected to be developed. Also in the electronic endoscopy field for example, high-speed digital signals are required to be transmitted with as few signal lines as possible; therefore, a transmission rate per signal line needs to be accelerated.

A transceiver performing such wired high-speed digital transmission is usually achieved as an integrated circuit (IC) using a semiconductor technique. Such a transceiver is often manufactured through a silicon complementary metal oxide semiconductor (CMOS) process that has achieved acceleration of transistors by process refinement and low cost by mass production.

As a wired transmission-rate acceleration technique, a technique to compensate for degradation of a signal waveform due to power loss in a transmission path is in practical use. In general, since a transmission path has a low-pass characteristic, high-frequency components (in particular, components of several GHz or more) contained in a transmission waveform are attenuated and jitter is increased due to interference between symbols on a receiver side. As the transmission distance becomes longer, it becomes more difficult to determine whether data are 0 or 1. In order to compensate for 0/1 determination of data on the receiver side, in particular, a pre-emphasis technique is widely used in which high-frequency components of transmission signals are reinforced in advance on a transmitter side.

An overview of the pre-emphasis technique will be briefly described below. Serial transmission is a technique to generate a bit string having a higher rate by serialiring a plurality of parallel data and to transmit the bit string from a transmitter side to a receiver side via one transmission path (or a pair of differential transmission paths). The bit string includes both portions where 0 and 1 are frequently changed and where 0 and 1 are continued with few changes. Due to the above-described low-pass characteristic of the transmission path, a swing value of a bit that is changed after continuation of 0 or 1 becomes small on the receiver side, so that an eye pattern tends to be broken.

Accordingly, the pre-emphasis technique increases the output swing when the bit is transmitted immediately after continuation of 0 or 1 and compensates for a decrease in the swing value on the receiver side, thereby securing a preferred eye pattern. Since a required amount of pre-emphasis depends on a characteristic of a transmission path, in order to optimize it automatically, JP 4990123B proposes an output driver circuit with improved resolution, for example.

### SUMMARY

The above-described pre-emphasis technique is a technique to compensate for frequency characteristics of a transmission path. However, the pre-emphasis technique cannot increase the maximum data rate that is decided by a slew rate of an output driver. In order to achieve transmission at higher speed, improved slew rate and substantial acceleration of an output driver of a transmission IC are expected.

Accordingly, according to the present disclosure, there are provided a semiconductor integrated circuit and an imaging device that are novel and improved and enable output of high-speed digital signals by operating at high speed.

According to an embodiment of the present disclosure, there is provided a semiconductor integrated circuit including at least one MOS transistor a source or drain of which is connected an output terminal, and a driver circuit configured to drive a back gate or a well of the MOS transistor in a manner that voltage swing is in a same phase as the output terminal.

According to another embodiment of the present disclosure, there is provided an imaging device including the semiconductor integrated circuit.

According to one or more of embodiments of the present disclosure, as described above, it is possible to a semiconductor integrated circuit and an imaging device that are novel and improved and enable output of high-speed digital signals by operating at high speed.

### BRIEF DESCRIPTION OF THE DRAWINGS

FIG. 1 is an explanatory view illustrating a configuration example of a MOS transistor;

FIG. 2A is an explanatory view illustrating a configuration example of an output driver circuit according to an embodiment of the present disclosure;

FIG. 2B is an explanatory view illustrating a specific configuration example of an output driver circuit 100a according to an embodiment of the present disclosure;

FIG. 3A is an explanatory view illustrating a case where a polarity of an output terminal OUT is in the same phase as a signal input to a gate 116;

FIG. 3B is an explanatory view illustrating a case where a polarity of an output terminal OUT is in an anti-phase of a signal input to the gate 116;

FIG. 4A is an explanatory view illustrating a configuration example of an output driver circuit 100b according to an embodiment of the present disclosure;

FIG. 4B is an explanatory view illustrating a specific configuration example of an output driver circuit 100b according to an embodiment of the present disclosure;

FIG. 4C is an explanatory view illustrating a configuration example of an output driver circuit 100a′ according to an embodiment of the present disclosure;

FIG. 4D is an explanatory view illustrating a configuration example of an output driver circuit 100a″ according to an embodiment of the present disclosure;

FIG. 4E is an explanatory view illustrating a configuration example of an output driver circuit 100b′ according to an embodiment of the present disclosure;

FIG. 5 is an explanatory view illustrating a specific configuration example of an output driver circuit according to an embodiment of the present disclosure;

FIG. 6 is an explanatory view illustrating a specific configuration example of an output driver circuit according to an embodiment of the present disclosure;

FIG. 7 is an explanatory view illustrating a specific configuration example of an output driver circuit according to an embodiment of the present disclosure;

FIG. 8 is an explanatory view illustrating a specific configuration example of an output driver circuit according to an embodiment of the present disclosure;

FIG. 9 is an explanatory view illustrating a specific configuration example of an output driver circuit according to an embodiment of the present disclosure;

FIG. 10 is an explanatory view illustrating a specific configuration example of an output driver circuit according to an embodiment of the present disclosure;

FIG. 11 is an explanatory view illustrating a specific configuration example of an output driver circuit according to an embodiment of the present disclosure;

FIG. 12 is an explanatory view illustrating a specific configuration example of an output driver circuit according to an embodiment of the present disclosure;

FIG. 13 is an explanatory view illustrating a specific configuration example of an output driver circuit according to an embodiment of the present disclosure;

FIG. 14 is an explanatory view illustrating a specific configuration example of an output driver circuit according to an embodiment of the present disclosure;

FIG. 15 is an explanatory view illustrating effects of an output driver circuit according to an embodiment of the present disclosure; and

FIG. 16 is an explanatory view illustrating a functional configuration example of an imaging device including an output driver circuit according to an embodiment of the present disclosure.

### DETAILED DESCRIPTION OF THE EMBODIMENT(S)

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

Note that the description will be made in the following order.

<1. Description of Existing Technique>

<2. Embodiment of Present Disclosure>

[Basic Configuration Example]

[Specific Configuration Examples (1) to (10)]

[Effects of Embodiment of Present Disclosure]

[Configuration Example of Imaging Device Including Output Driver Circuit]

<3. Conclusion>

### 1. DESCRIPTION OF EXISTING TECHNIQUE

First, prior to description of a preferred embodiment of the present disclosure, an existing technique will be described. After explanation of problems in the existing technique, the preferred embodiment of the present disclosure to solve the problems will be described in detail.

One of factures that prevent high-speed operation of an output driver of a transmission IC is a parasitic capacitance in a MOS transistor that forms a final output stage. In particular, in a terminal (drain terminal or source terminal) of a transistor that is connected to an output terminal, charge/discharge to the parasitic capacitance occurs by voltage swing. The charge/discharge to the parasitic capacitance blunts an output waveform, resulting in a decrease in slew rate. A dominant parasitic capacitance exists among the drain terminal or the source terminal, a gate terminal, and a well.

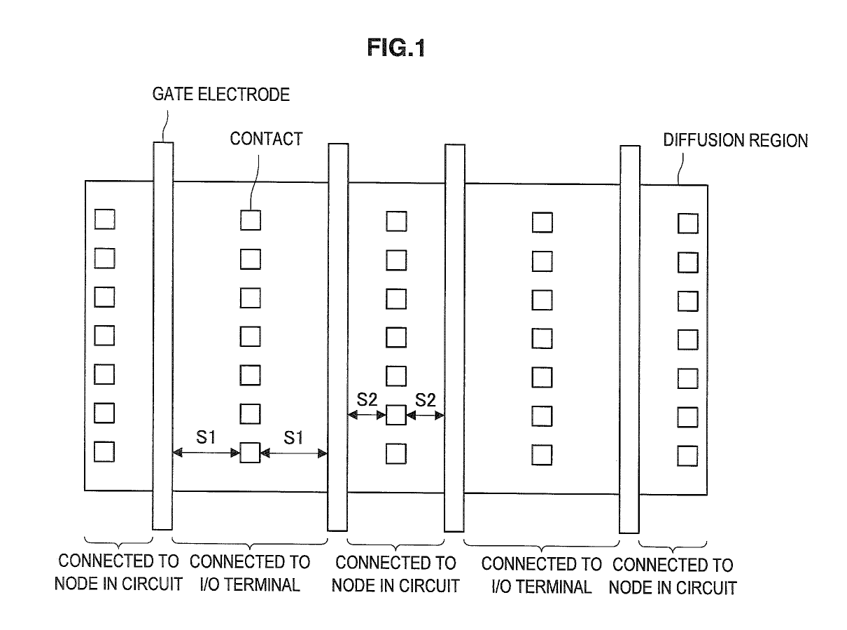

In a general circuit that is connected to a terminal inside an IC, a structure is provided so as to prevent breaking of an element such as a transistor due to electrostatic discharge (ESD) or breaking of metal wiring or the like due to heat generation when discharge current is flowing. FIG. 1 is an explanatory view illustrating a configuration example of a MOS transistor. In particular, as for the MOS transistor that forms the final output stage, in a drain region or a source region that is connected to an I/O terminal, as illustrated in FIG. 1, there are restrictions such that the distance (S1 in FIG. 1) between a contact and the gate electrode is longer than other portions (S2 in FIG. 1) in many cases. In those cases, the parasitic capacitance between the drain region or the source region and a back gate (or the well) increases more remarkably.

Accordingly, the preferred embodiment of the present disclosure that enables output of high-speed digital signals even when a large parasitic capacitance exists between the terminal connected to the output terminal (I/O terminal) and the back gate (or the well) of the MOS transistor will be described in detail below.

### 2. EMBODIMENT OF PRESENT DISCLOSURE

### Basic Configuration Example

An embodiment of the present disclosure will show an output driver circuit that is provided with a means for driving a back gate (well) of a transistor at a final output stage so as to drive the back gate to swing to have the same polarity as an output signal. A basic configuration example and functions of the output driver circuit that drives the back gate to swing to have the same polarity as the output signal will be described.

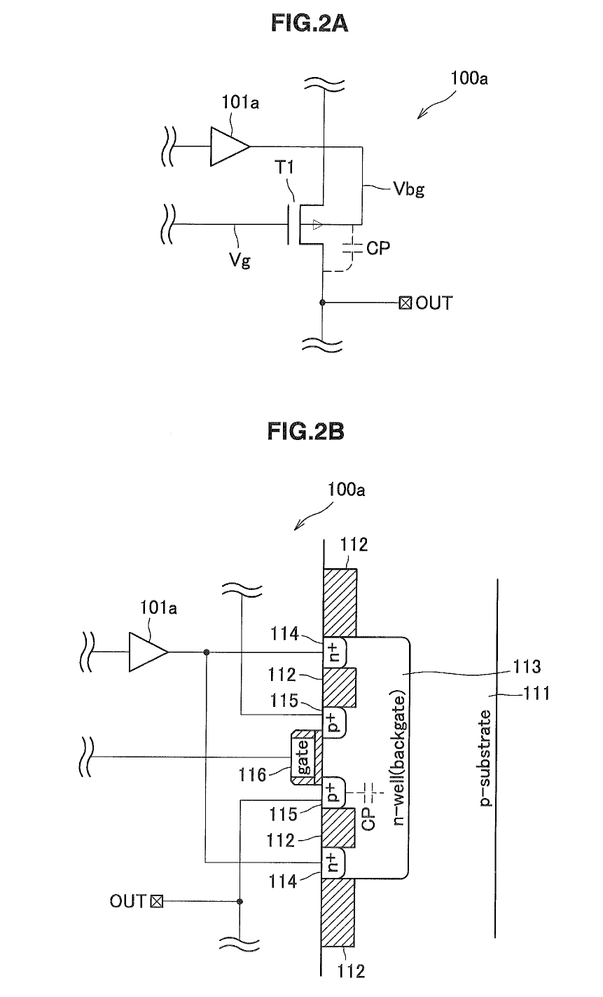

First, a configuration example and functions when the final output stage transistor is a PMOS will be described. FIG. 2A is an explanatory view illustrating a configuration example of an output driver circuit 100a according to an embodiment of the present disclosure. The output driver circuit 100a according to an embodiment of the present disclosure illustrated in FIG. 2A is configured with a final output stage transistor T1, a driver 101a that drives a back gate of T1, and an output terminal OUT.

FIG. 2B is an explanatory view illustrating a specific configuration example of the output driver circuit 100a according to an embodiment of the present disclosure. FIG. 2B illustrates a cross section of the final output stage transistor T1 in a twin well or triple well CMOS process using a p-type wafer. FIG. 2B illustrates a p-type substrate 111, isolations 112, an n-type well 113, n-type high concentration diffusion regions 114, p-type high concentration diffusion regions 115, and a gate 116.

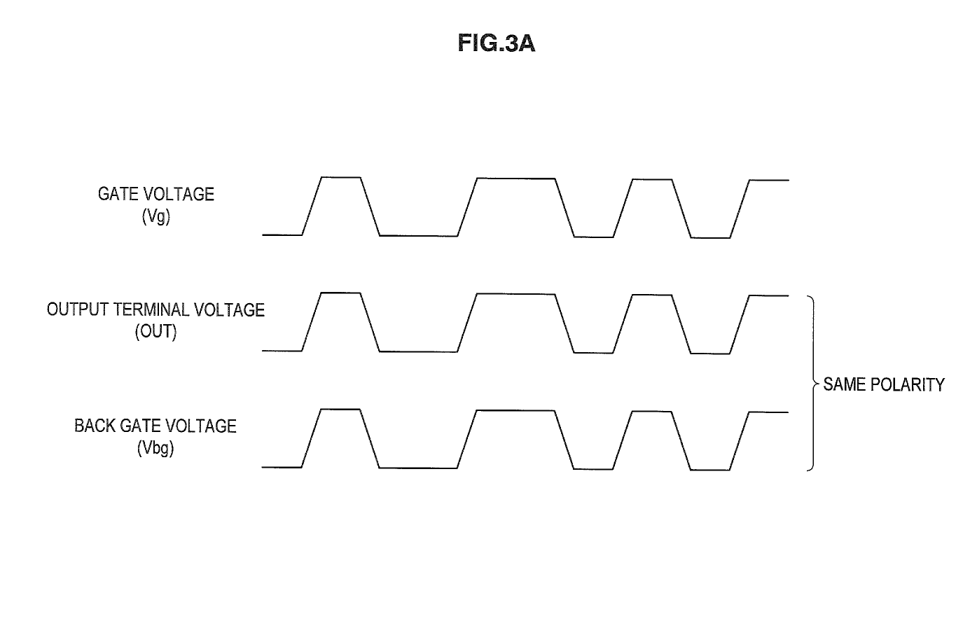

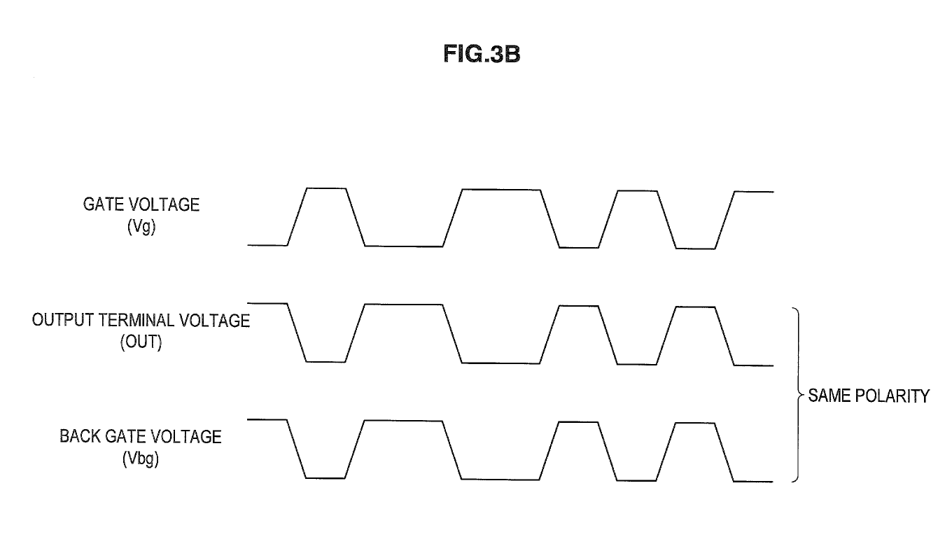

As for the output driver circuit 100a according to an embodiment of the present disclosure illustrated in FIGS. 2A and 2B, whether a polarity of the output terminal OUT is in the same phase as or the anti-phase of an signal input to the gate is decided depending on a circuit configuration (e.g., source follower or common source) at the output stage. FIG. 3A is an explanatory view illustrating a case where the polarity of the output terminal OUT is in the same phase as the signal input to the gate 116. When the polarity of the output terminal OUT is in the same phase as the signal input to the gate 116, the back gate is driven with a signal in the same phase as the signal input to the gate 116, so that the back gate swings in the same phase as the output terminal OUT.

FIG. 3B is an explanatory view illustrating a case where the polarity of the output terminal OUT is in the anti-phase of the signal input to the gate 116. When the polarity of the output terminal OUT is in the anti-phase of the signal input to the gate 116, the back gate is driven with a signal in the anti-phase of the signal input to the gate 116, so that the back gate swings in the same phase as the output terminal OUT.

The output driver circuit 100a according to an embodiment of the present disclosure operates in this manner, and accordingly, the charge/discharge to a parasitic capacitance CP existing between the output terminal OUT and the back gate is suppressed and the existence of the parasitic capacitance CP can be equivalently negligible. The equivalently negligible existence of the parasitic capacitance CP prevents output current from the final output stage transistor T1 from being consumed by the charge/discharge to the parasitic capacitance CP, and the output current is effectively supplied to the output terminal OUT (and an output load resistance when the output load resistance is connected in parallel with the output terminal OUT). The effective supplement of the output current from the final output stage transistor T1 to the output terminal OUT enables the output driver circuit 100a according to an embodiment of the present disclosure to prevent a decrease in slew rate.

In contrast, when electricity is fed to the back gate by a fixed potential such as VDD (power source voltage on a high potential side), the voltage between the output terminal OUT and the back gate varies according to a change in output voltage. Therefore, the charge/discharge of the parasitic capacitance CP existing between the output terminal OUT and the back gate causes part of the output current from the final output stage transistor to be consumed. Therefore, when electricity is fed to the back gate by a fixed potential such as VDD (power source voltage on a high potential side), the slew rate is decreased.

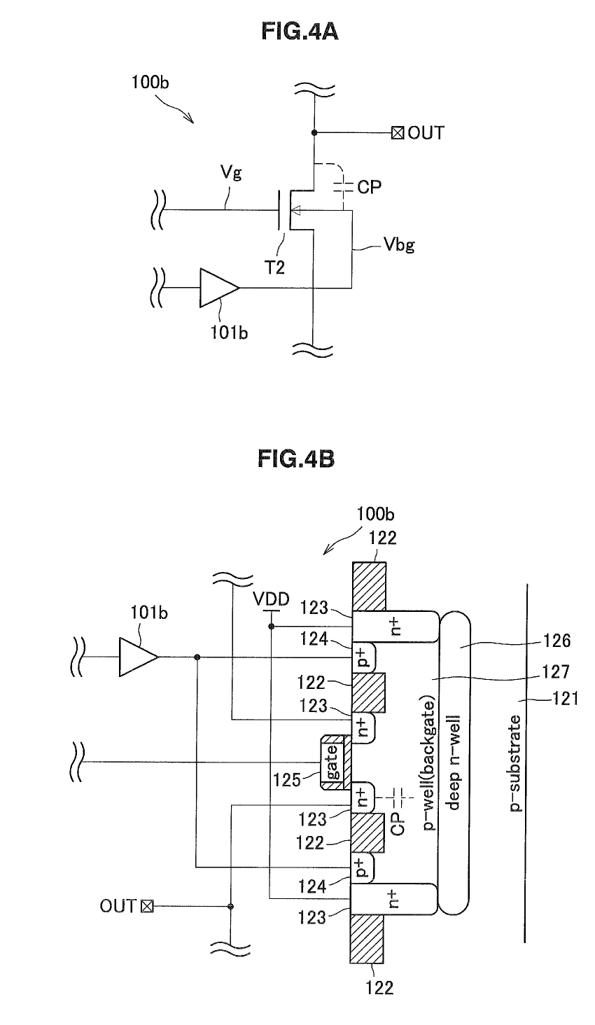

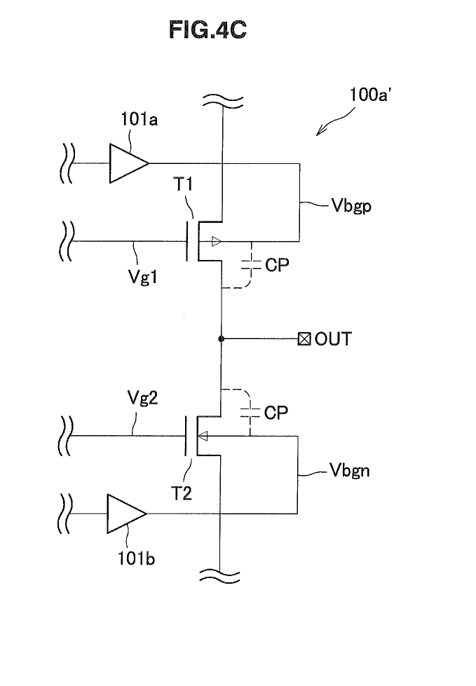

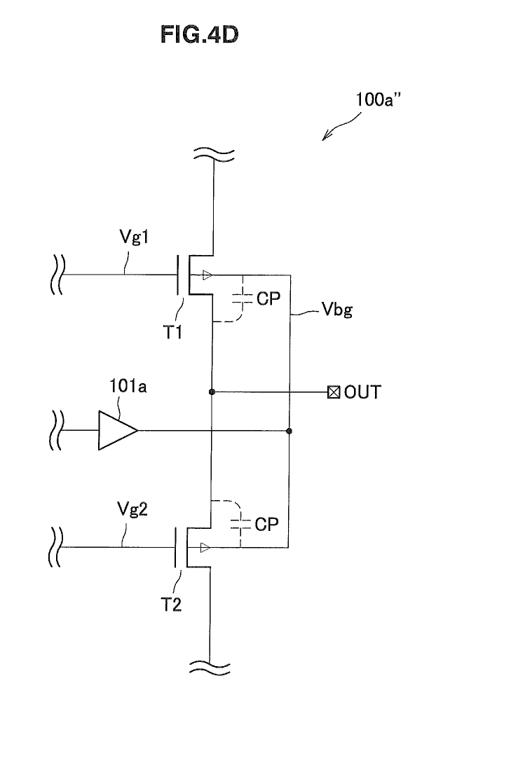

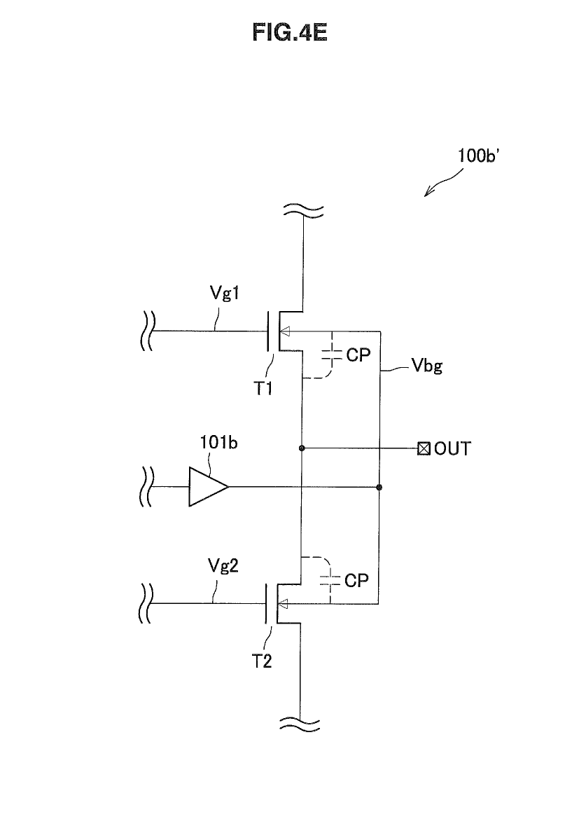

A case where the final output stage transistor T1 is the PMOS has been described above. Subsequently, a configuration example and functions when the final output stage transistor is an NMOS will be described. FIG. 4A is an explanatory view illustrating a configuration example of an output driver circuit 100b according to an embodiment of the present disclosure. The output driver circuit 100b according to an embodiment of the present disclosure illustrated in FIG. 4A is configured with a final output stage transistor T2, a driver 101b that drives a back gate of T2, and an output terminal OUT.

FIG. 4B is an explanatory view illustrating a specific configuration example of the output driver circuit 100b according to an embodiment of the present disclosure. FIG. 4B illustrates a cross section of the final output stage transistor T2 in a triple well CMOS process using a p-type wafer. FIG. 4B illustrates a p-type substrate 121, isolations 122, n-type high concentration diffusion regions 123, p-type high concentration diffusion regions 124, a gate 125, a deep n-type well 126, and a p-type well 127.

As for the output driver circuit 100b according to an embodiment of the present disclosure illustrated in FIGS. 4A and 4B, whether a polarity of the output terminal OUT is in the same phase as or the anti-phase of an signal input to the gate is decided depending on a circuit configuration (e.g., configuration of source follower or common source) at the output stage. FIG. 3A is an explanatory view illustrating a case where the polarity of the output terminal OUT is in the same phase as the signal input to the gate 125. When the polarity of the output terminal OUT is in the same phase as the signal input to the gate 125, the back gate is driven with a signal in the same phase as the signal input to the gate 125, so that the back gate swings in the same phase as the output terminal OUT.

FIG. 3B is an explanatory view illustrating a case where the polarity of the output terminal OUT is in the anti-phase of the signal input to the gate 125. When the polarity of the output terminal OUT is in the anti-phase of the signal input to the gate 125, the back gate is driven with a signal in the anti-phase of the signal input to the gate 125, so that the back gate swings in the same phase as the output terminal OUT.

The output driver circuit 100b according to an embodiment of the present disclosure operates in this manner, and accordingly, the charge/discharge to a parasitic capacitance CP existing between the output terminal OUT and the back gate is suppressed and the existence of the parasitic capacitance CP can be equivalently negligible. The equivalently negligible existence of the parasitic capacitance CP prevents output current from the final output stage transistor T2 from being consumed by the charge/discharge to the parasitic capacitance CP, and the output current is effectively supplied to the output terminal OUT (and an output load resistance when the output load resistance is connected in parallel with the output terminal OUT). The effective supplement of the output current from the final output stage transistor T2 to the output terminal OUT enables the output driver circuit 100b according to an embodiment of the present disclosure to prevent a decrease in slew rate.

In contrast, when electricity is fed to the back gate by a fixed potential such as VSS (GND or power source voltage on a low potential side), the voltage between the output terminal OUT and the back gate varies according to a change in output voltage. Therefore, the charge/discharge of the parasitic capacitance CP existing between the output terminal OUT and the back gate causes part of the output current from the final output stage transistor to be consumed. Therefore, when electricity is fed to the back gate by a fixed potential such as VSS (GND or power source voltage on a low potential side), the slew rate is decreased.

In this manner, by providing a means for driving a back gate (well) of a transistor at a final output stage so as to drive the back gate to swing to have the same polarity as an output signal, it is possible to suppress charge/discharge to a parasitic capacitance existing between the output terminal and the back gate (well) in the output driver circuits 100a and 100b and to prevent a decrease in slew rate. The prevention of a decrease in slew rate enables the output driver circuits 100a and 100b to output signals having a high-speed data rate.

FIG. 2A illustrates a case where the final output stage transistor T1 is the PMOS transistor and FIG. 4A illustrates a case where the final output stage transistor T2 is the NMOS transistor. According to this embodiment, it is also possible to provide an output driver circuit including both the configurations illustrated in FIG. 2A and FIG. 4A. FIG. 4C is an explanatory view illustrating a configuration example of an output driver circuit 100a′ according to an embodiment of the present disclosure. The output driver circuit 100a′ illustrated in FIG. 4C includes both the configurations of the output driver circuit 100a illustrated in FIG. 2A and the output driver circuit 100b illustrated in FIG. 4A. By driving the respective back gates of the final output stage transistors T1 and T2 so as to swing to have the same polarity as an output signal, it is possible to suppress charge/discharge to a parasitic capacitance existing between the output terminal and the back gate (well) in the output driver circuit 100a′ illustrated in FIG. 4C and to prevent a decrease in slew rate. Further, FIG. 4D is an explanatory view illustrating a configuration example of an output driver circuit 100a″ according to an embodiment of the present disclosure, and FIG. 4E is an explanatory view illustrating a configuration example of an output driver circuit 100b′ according to an embodiment of the present disclosure. FIG. 4D illustrates the output driver circuit 100a″ in which two PMOS transistors T1 and T2 are disposed in series, and FIG. 4E illustrates the output driver circuit 100b′ in which two NMOS transistors T1 and T2 are disposed in series. Even when the output driver circuit has such configurations, by driving the respective the back gates with the drivers 101a and 101b to swing to have the same polarity as an output signal, it is possible to suppress charge/discharge to a parasitic capacitance existing between the output terminal and the back gate (well) and to prevent a decrease in slew rate.

The basic configuration example and functions of the output driver circuit that drives the back gate to swing to have the same polarity as the output signal have been described above. Subsequently, a specific configuration example of an output driver circuit that drives a back gate to swing to have the same polarity as the output signal will be described in detail.

### Specific Configuration Example (1)

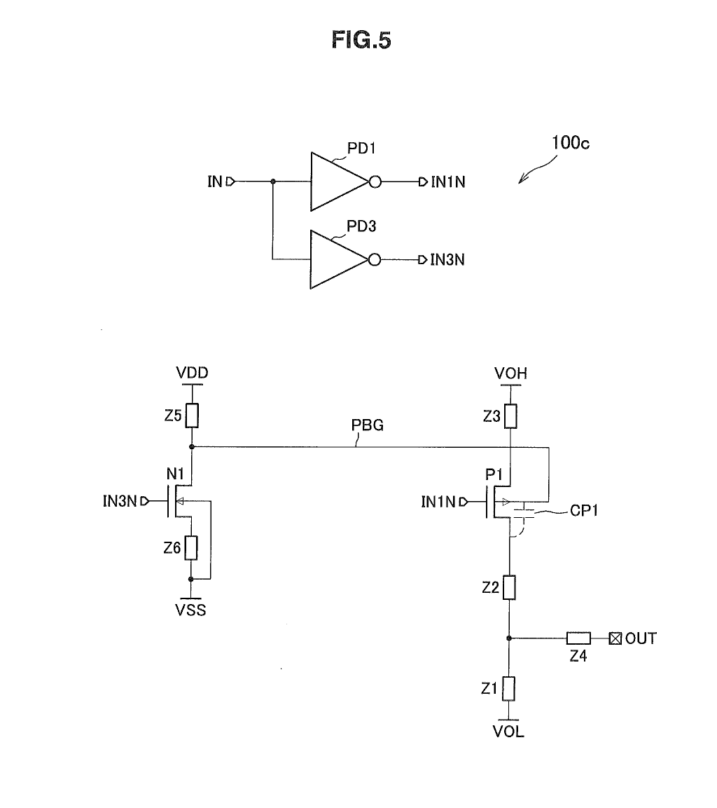

FIG. 5 is an explanatory view illustrating a specific configuration example of an output driver circuit according to an embodiment of the present disclosure. FIG. 5 illustrates an output driver circuit 100c. The output driver circuit 100c illustrated in FIG. 5 is a common-source single-ended output driver circuit in which a final output stage transistor P1 is formed with a PMOS.

An input signal from IN illustrated in FIG. 5 is buffered in the output driver circuit 100c and is output from OUT. The input signal from IN is converted to IN1N and IN3N in pre-drivers PD1 and PD3, respectively. An unillustrated impedance Z0 is connected outside OUT.

Impedances Z2 and Z4 illustrated in FIG. 5 may be added in order to adjust the impedance, but are not necessarily provided. Therefore, the impedances Z2 and Z4 are regarded as zero and negligible in the following description.

A final output stage of the output driver circuit 100c is formed with a PMOS transistor P1, a source impedance Z3, and a load impedance Z1. A source terminal of the transistor P1 is short-circuited to a high-potential side power source VOH for the final output stage by the source impedance Z3. A drain terminal of the transistor P1 is connected to OUT and is short-circuited to a low-potential side power source VOL for the final output stage by the load impedance Z1. Note that the load impedance Z1 is not necessarily incorporated in an LSI, and a load impedance corresponding to the load impedance Z1 may be mounted by a separate off-chip or may be omitted. Since the final output stage of the output driver circuit 100c illustrated in FIG. 5 has a common source structure, voltage swing of OUT is in the anti-phase of IN1N, i.e., in the same phase as IN.

A driver circuit of a back gate terminal PBG of the final output stage transistor P1 formed with the PMOS is configured with a transistor N1 formed with an NMOS, a source impedance Z6, and a load impedance Z5. A source terminal of the transistor N1 is short-circuited to a low-potential side power source VSS by the source impedance Z6. A drain terminal of the transistor N1 is short-circuited to a high-potential side power source VDD by the load impedance Z5 and is connected to the back gate terminal PBG. Since the driver circuit of the back gate terminal PBG of the output driver circuit 100c illustrated in FIG. 5 has a common source structure, voltage swing of the back gate terminal PBG is in the anti-phase of IN3N, i.e., in the same phase as N.

The output driver circuit 100c illustrated in FIG. 5 operates such that the voltage swing of the back gate terminal PBG of the final output stage transistor P1 is in the same phase as the output terminal OUT. Accordingly, by setting a voltage-swing value of the back gate terminal PBG to an appropriate value, the charge/discharge to a parasitic capacitance CP1 can be suppressed.

### Specific Configuration Example (2)

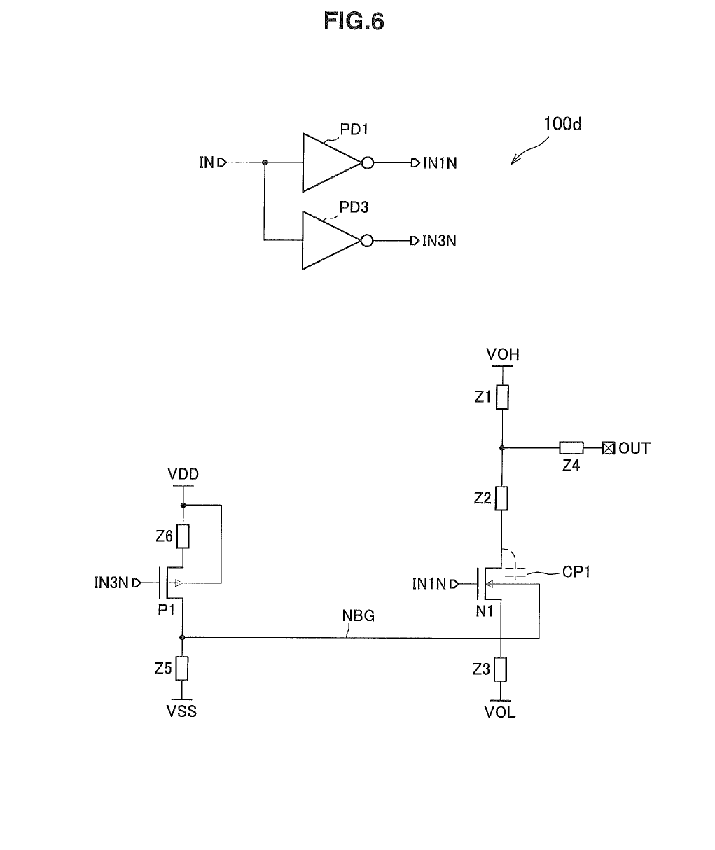

FIG. 6 is an explanatory view illustrating a specific configuration example of an output driver circuit according to an embodiment of the present disclosure. FIG. 6 illustrates an output driver circuit 100d. The output driver circuit 100d illustrated in FIG. 6 is a common-source single-ended output driver circuit in which a final output stage transistor N1 is formed with an NMOS.

An input signal from IN illustrated in FIG. 6 is buffered in the output driver circuit 100d and is output from OUT. The input signal from IN is converted to IN1N and IN3N in pre-drivers PD1 and PD3, respectively. An unillustrated impedance Z0 is connected outside OUT.

Impedances Z2 and Z4 illustrated in FIG. 6 may be added in order to adjust the impedance, but are not necessarily provided. Therefore, the impedances Z2 and Z4 are regarded as zero and negligible in the following description.

A final output stage of the output driver circuit 100d illustrated in FIG. 6 is formed with a transistor N1, a source impedance Z3, and a load impedance Z1. A source terminal of the transistor N1 is short-circuited to a low-potential side power source VOL for the final output stage by the source impedance Z3. A drain terminal of the transistor P1 is connected to OUT and is short-circuited to a high-potential side power source VOH for the final output stage by the load impedance Z1. Note that the load impedance Z1 is not necessarily incorporated in an LSI, and a load impedance corresponding to the load impedance Z1 may be mounted by a separate off-chip or may be omitted. Since the final output stage of the output driver circuit 100d illustrated in FIG. 6 has a common source structure, voltage swing of OUT is in the anti-phase of IN1N, i.e., in the same phase as IN.

A driver circuit of a back gate terminal NBG of the final output stage transistor N1 formed with the NMOS is configured with a transistor P1 formed with a PMOS, a source impedance Z6, and a load impedance Z5. A source terminal of the transistor P1 is short-circuited to a high-potential side power source VDD by the source impedance Z6. A drain terminal of the transistor P1 is short-circuited to a low-potential side power source VSS by the load impedance Z5 and is connected to the back gate terminal NBG. Since the driver circuit of the back gate terminal NBG of the output driver circuit 100d illustrated in FIG. 6 has a common source structure, voltage swing of the back gate terminal NBG is in the anti-phase of IN3N, i.e., in the same phase as N.

The output driver circuit 100d illustrated in FIG. 6 operates such that the voltage swing of the back gate terminal NBG of the final output stage transistor N1 is in the same phase as the output terminal OUT. Accordingly, by setting a voltage-swing value of the back gate terminal NBG to an appropriate value, the charge/discharge to a parasitic capacitance CP1 can be suppressed.

### Specific Configuration Example (3)

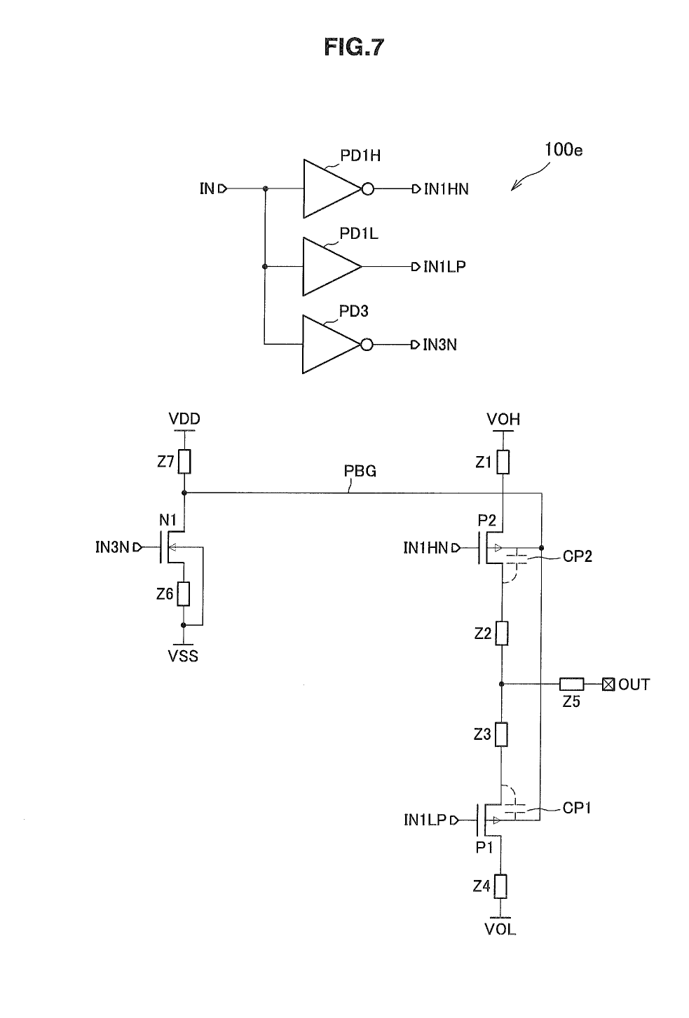

FIG. 7 is an explanatory view illustrating a specific configuration example of an output driver circuit according to an embodiment of the present disclosure. FIG. 7 illustrates an output driver circuit 100e. The output driver circuit 100e illustrated in FIG. 7 is a push-pull single-ended output driver circuit in which final output stage transistors are formed with two PMOSs.

An input signal from IN illustrated in FIG. 7 is buffered in the output driver circuit 100e and is output from OUT. The input signal from IN is converted to IN1HN, IN1LP, and IN3N in pre-drivers PD1H, PD1L, and PD3, respectively. An unillustrated impedance Z0 is connected outside OUT.

Impedances Z2, Z3, and Z5 illustrated in FIG. 7 may be added in order to adjust the impedance, but are not necessarily provided. Therefore, the impedances Z2, Z3, and Z5 are regarded as zero and negligible in the following description.

A final output stage of the output driver circuit 100e illustrated in FIG. 7 is formed with PMOS transistors P1 and P2 and impedances Z1 and Z4. A source terminal of the transistor P2 is short-circuited to a high-potential side power source VOH for the final output stage by the source impedance Z1, and a drain terminal thereof is connected to OUT. A source terminal of the transistor P1 is connected to OUT and a drain terminal thereof is short-circuited to a low-potential side power source VOL for the final output stage by the impedance Z4. Since the final output stage of the output driver circuit 100e illustrated in FIG. 7 has a push-pull structure, voltage swing of OUT is in the anti-phase of IN1HN and in the same phase as IN1LP, i.e., in the same phase as IN.

A driver circuit of a back gate terminal PBG of the final output stage transistors P1 and P2 each formed with the PMOS is configured with a transistor N1 formed with an NMOS, a source impedance Z6, and a load impedance Z7. A source terminal of the transistor N1 is short-circuited to a low-potential side power source VSS by the source impedance Z6. A drain terminal of the transistor N1 is short-circuited to a high-potential side power source VDD by the load impedance Z7 and is connected to the back gate terminal PBG. Since the driver circuit of the back gate terminal PBG of the output driver circuit 100e illustrated in FIG. 7 has a common source structure, voltage swing of the back gate terminal PBG is in the anti-phase of IN3N, i.e., in the same phase as IN.

The output driver circuit 100e illustrated in FIG. 7 operates such that the voltage swing of the back gate terminal PBG of the two final output stage PMOS transistors P1 and P2 is in the same phase as the output terminal OUT. Accordingly, by setting a voltage-swing value of the back gate terminal PBG to an appropriate value, the charge/discharge to parasitic capacitances CP1 and CP2 can be suppressed.

### Specific Configuration Example (4)

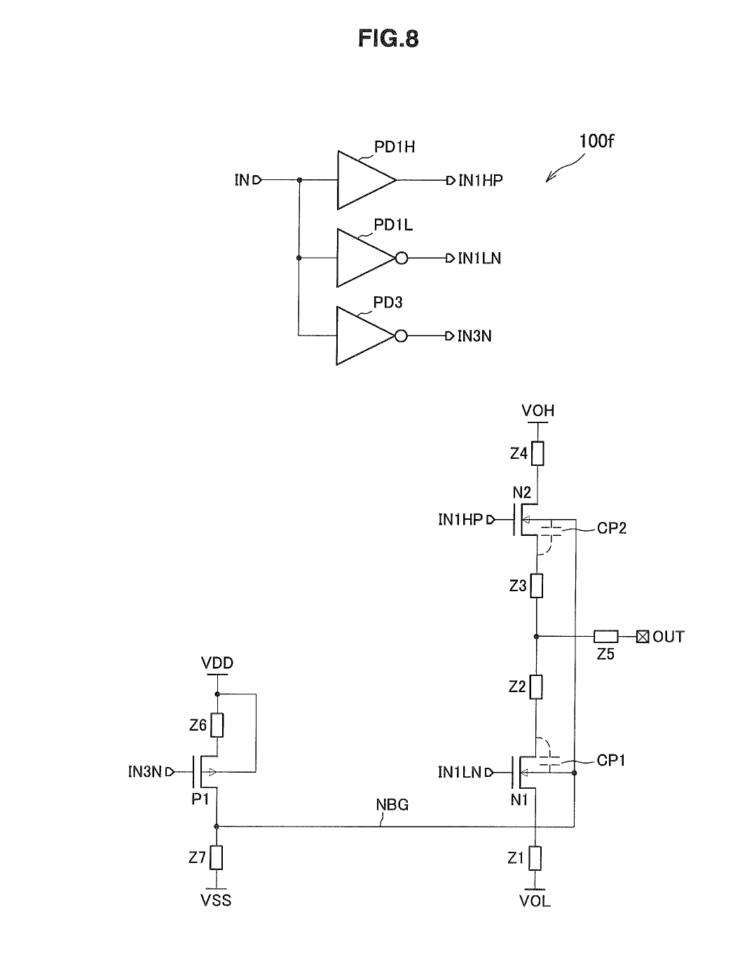

FIG. 8 is an explanatory view illustrating a specific configuration example of an output driver circuit according to an embodiment of the present disclosure. FIG. 8 illustrates an output driver circuit 100f. The output driver circuit 100f illustrated in FIG. 8 is a push-pull single-ended output driver circuit in which final output stage transistors are formed with two NMOSs.

An input signal from IN illustrated in FIG. 8 is buffered in the output driver circuit 100f and is output from OUT. The input signal from IN is converted to IN1HP, IN1LN, and IN3N in pre-drivers PD1H, PD1L, and PD3, respectively. An unillustrated impedance Z0 is connected outside OUT.

Impedances Z2, Z3, and Z5 illustrated in FIG. 8 may be added in order to adjust the impedance, but are not necessarily provided. Therefore, the impedances Z2, Z3, and Z5 are regarded as zero and negligible in the following description.

A final output stage of the output driver circuit 100f illustrated in FIG. 8 is formed with NMOS transistors N1 and N2 and impedances Z1 and Z4. A source terminal of the transistor N1 is short-circuited to a low-potential side power source VOL for the final output stage by the impedance Z1 and a drain terminal thereof is connected to OUT. A source terminal of the transistor N2 is connected to OUT and a drain terminal thereof is short-circuited to a high-potential side power source VOH for the final output stage by the impedance Z4. Since the final output stage of the output driver circuit 100f illustrated in FIG. 8 has a push-pull structure, voltage swing of OUT is in the anti-phase of IN1LN and in the same phase as IN1HP, i.e., in the same phase as N.

A driver circuit of a back gate terminal NBG of the final output stage transistors N1 and N2 each formed with the NMOS is configured with a transistor P1 formed with a PMOS, a source impedance Z6, and a load impedance Z7. A source terminal of the transistor P1 is short-circuited to a high-potential side power source VDD by the source impedance Z6. A drain terminal of the transistor P1 is short-circuited to a low-potential side power source VSS by the load impedance Z7 and is connected to the back gate terminal NBG. Since the driver circuit of the back gate terminal NBG of the output driver circuit 100f illustrated in FIG. 8 has a common source structure, voltage swing of the back gate terminal NBG is in the anti-phase of IN3N, i.e., in the same phase as N.

The output driver circuit 100f illustrated in FIG. 8 operates such that the voltage swing of the back gate terminal NBG of the two final output stage NMOS transistors N1 and N2 is in the same phase as the output terminal OUT. Accordingly, by setting a voltage-swing value of the back gate terminal NBG to an appropriate value, the charge/discharge to parasitic capacitances CP1 and CP2 can be suppressed.

### Specific Configuration Example (5)

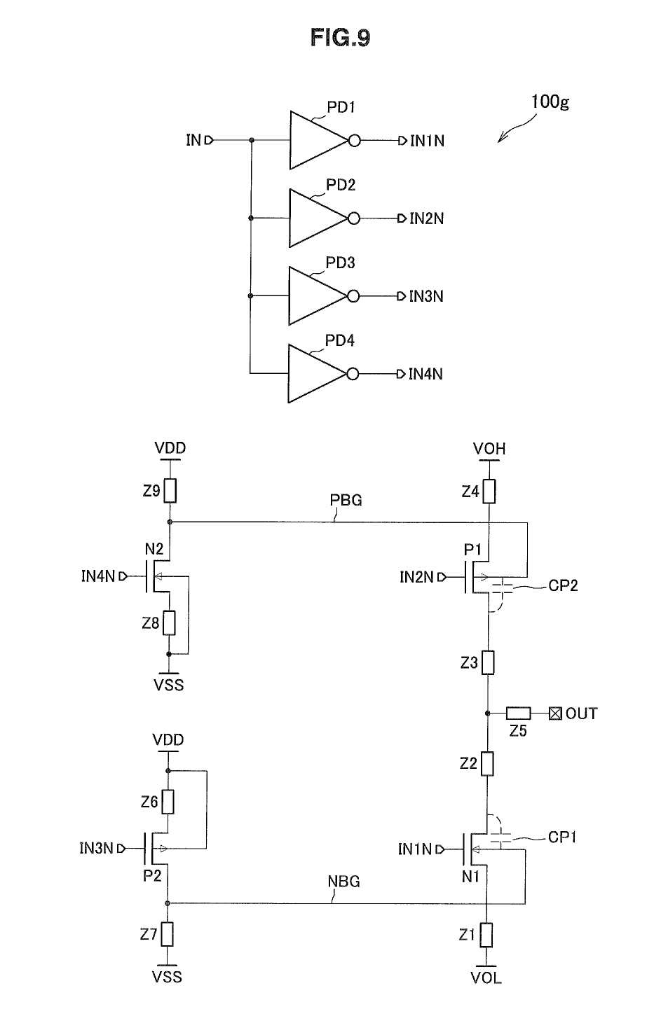

FIG. 9 is an explanatory view illustrating a specific configuration example of an output driver circuit according to an embodiment of the present disclosure. FIG. 9 illustrates an output driver circuit 100g. The output driver circuit 100g illustrated in FIG. 9 is an inverter single-ended output driver circuit in which final output stage transistors are formed with an NMOS and a PMOS.

An input signal from IN illustrated in FIG. 9 is buffered in the output driver circuit 100g and is output from OUT. The input signal from IN is converted to IN1N, IN2N, IN3N, and IN4N in pre-drivers PD1, PD2, PD3, and PD4, respectively. An unillustrated impedance Z0 is connected outside OUT.

Impedances Z2, Z3, and Z5 illustrated in FIG. 9 may be added in order to adjust the impedance, but are not necessarily provided. Therefore, the impedances Z2, Z3, and Z5 are regarded as zero and negligible in the following description.

A final output stage of the output driver circuit 100g is formed with a PMOS transistor P1, an NMOS transistor N1, and impedances Z1 and Z4. A source terminal of the transistor P1 is short-circuited to a high-potential side power source VOH for the final output stage by the impedance Z4, and a drain terminal thereof is connected to OUT. A source terminal of the transistor N1 is short-circuited to a low-potential side power source VOL for the final output stage by the impedance Z1, and a drain terminal thereof is connected to OUT. Since the final output stage of the output driver circuit 100g illustrated in FIG. 9 has an inverter structure, voltage swing of OUT is in the anti-phase of IN1N and IN2N, i.e., in the same phase as IN.

A driver circuit of a back gate terminal PBG of the final output stage transistor P1 formed with the PMOS is configured with a transistor N2 formed with an NMOS, a source impedance Z8, and a load impedance Z9. A source terminal of the transistor N2 is short-circuited to a low-potential side power source VSS by the source impedance Z8. A drain terminal of the transistor N2 is short-circuited to a high-potential side power source VDD by the load impedance Z9 and is connected to the back gate terminal PBG. Since the driver circuit of the back gate terminal PBG of the output driver circuit 100g illustrated in FIG. 9 has a common source structure, voltage swing of the back gate terminal PBG is in the anti-phase of IN4N, i.e., in the same phase as N.

A driver circuit of a back gate terminal NBG of the final output stage transistor N1 formed with the NMOS is configured with a transistor P2 formed with a PMOS, a source impedance Z6, and a load impedance Z7. A source terminal of the transistor P2 is short-circuited to a high-potential side power source VDD by the source impedance Z6. A drain terminal of the transistor P2 is short-circuited to a low-potential side power source VSS by the load impedance Z7 and is connected to the back gate terminal NBG. Since the driver circuit of the back gate terminal NBG of the output driver circuit 100g illustrated in FIG. 9 has a common source structure, voltage swing of the back gate terminal NBG is in the anti-phase of IN3N, i.e., in the same phase as N.

The output driver circuit 100g illustrated in FIG. 9 operates such that the voltage swing of the back gate terminal PBG of the final output stage PMOS transistor and of the back gate terminal NBG of the final output stage NMOS transistor is in the same phase as the output terminal OUT. Accordingly, by setting voltage-swing values of the back gate terminals PBG and NBG to appropriate values, the charge/discharge to parasitic capacitances CP1 and CP2 can be suppressed.

### Specific Configuration Example (6)

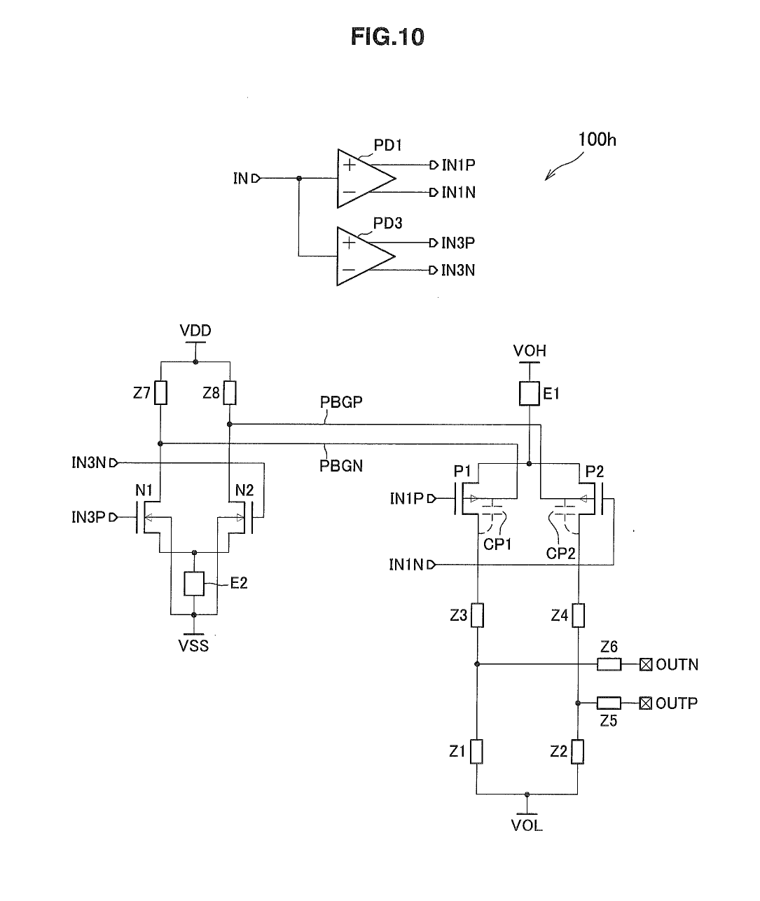

FIG. 10 is an explanatory view illustrating a specific configuration example of an output driver circuit according to an embodiment of the present disclosure. FIG. 10 illustrates an output driver circuit 100h. The output driver circuit 100h illustrated in FIG. 10 is a common-source differential output driver circuit in which a final output stage transistor is formed with two PMOSs.

An input signal from IN illustrated in FIG. 10 is buffered in the output driver circuit 100h and is output from OUTP and OUTN. The input signal from IN is converted to IN1P and IN1N in a pre-driver PD1 and to IN3P and IN3N in a pre-driver PD3. An unillustrated differential characteristic impedance ZD0 is connected between OUTP and OUTN.

Impedances Z3, Z4, Z5, and Z6 illustrated in FIG. 10 may be added in order to adjust the impedance, but are not necessarily provided. Therefore, the impedances Z3, Z4, Z5, and Z6 are regarded as zero and negligible in the following description.

A final output stage of the output driver circuit 100h is formed with a differential pair formed of PMOS transistors P1 and P2, a current source formed of an active element or an impedance E1 formed of a passive element, and load impedances Z1 and Z2. Drain terminals of the differential pair are connected to OUTP and OUTN, respectively, and are short-circuited to a low-potential side power source VOL for the final output stage by the load impedances Z1 and Z2. Note that the load impedances Z1 and Z2 are not necessarily incorporated in an LSI, and load impedances corresponding to the load impedances Z1 and Z2 may be mounted by a separate off-chip or may be omitted. Current supplied to the differential pair from the current source or the impedance E1 is switched by a potential difference between IN1P and IN1N, and then supplied to the differential characteristic impedance ZD0 of a differential transmission path connected to the load impedances Z1 and Z2, OUTP, and OUTN. Since the final output stage of the output driver circuit 100h illustrated in FIG. 10 has a differential common-source structure, voltage swing of OUTP is in the anti-phase of IN1N and voltage swing of OUTN is in the anti-phase of IN1P.

A driver circuit of back gate terminals PBGN and PBGP of the final output stage transistors P1 and P2 each formed with the PMOS is configured with a differential pair formed of NMOS transistors N1 and N2, a current source formed of an active element or an impedance E2 formed of a passive element, and load impedances Z7 and Z8. Source terminals of the transistors N1 and N2 are short-circuited to a low-potential side power source VSS by the current source or the impedance E2. Drain terminals of the differential pair are connected to back gate terminals PBGP and PBGN and are short-circuited to a high-potential side power source VDD by the load impedances Z7 and Z8. Current supplied to the differential pair from the current source or the impedance E2 is switched by a potential difference between IN3P and IN3N, and then supplied to the load impedances Z7 and Z8. Since the driver circuit of the back gate terminals PBGN and PBGP of the output driver circuit 100h illustrated in FIG. 10 has a differential common-source structure, voltage swing of the back gate terminal PBGP is in the anti-phase of IN3N, and voltage swing of the back gate terminal PBGN is in the anti-phase of IN3P.

The output driver circuit 100h illustrated in FIG. 10 operates such that the voltage swing of the back gate terminals PBGN and PBGP of the two final output stage PMOS transistors is in the same phase as the output terminals OUTP and OUTN, respectively, to which the respective drain terminals are connected. Accordingly, by setting voltage-swing values of the back gate terminals PBGP and PBGN to appropriate values, the charge/discharge to parasitic capacitances CP1 and CP2 can be suppressed.

### Specific Configuration Example (7)

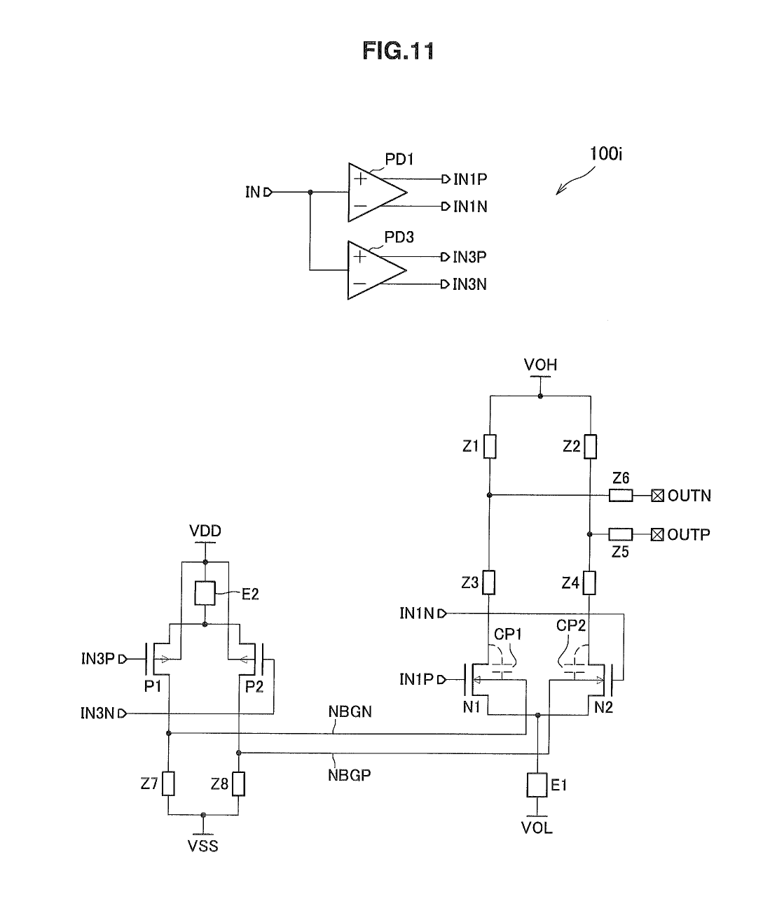

FIG. 11 is an explanatory view illustrating a specific configuration example of an output driver circuit according to an embodiment of the present disclosure. FIG. 11 illustrates an output driver circuit 100i. The output driver circuit 100i illustrated in FIG. 11 is a common-source differential output driver circuit in which a final output stage transistor is formed with two NMOSs.

An input signal from IN illustrated in FIG. 11 is buffered in the output driver circuit 100i and is output from OUTP and OUTN. The input signal from IN is converted to IN1P and IN1N in a pre-driver PD1 and to IN3P and IN3N in a pre-driver PD3. An unillustrated differential characteristic impedance ZD0 is connected between OUTP and OUTN.

Impedances Z3, Z4, Z5, and Z6 illustrated in FIG. 11 may be added in order to adjust the impedance, but are not necessarily provided. Therefore, the impedances Z3, Z4, Z5, and Z6 are regarded as zero and negligible in the following description.

A final output stage of the output driver circuit 100i is formed with a differential pair formed of NMOS transistors N1 and N2, a current source formed of an active element or an impedance E1 formed of a passive element, and load impedances Z1 and Z2. Drain terminals of the differential pair are connected to OUTP and OUTN and are short-circuited to a high-potential side power source VOH for the final output stage by the load impedances Z1 and Z2. Note that the load impedances Z1 and Z2 are not necessarily incorporated in an LSI, and load impedances corresponding to the load impedances Z1 and Z2 may be mounted by a separate off-chip or may be omitted. Current supplied to the differential pair from the current source or the impedance E1 is switched by a potential difference between IN1P and IN1N, and then supplied to the differential characteristic impedance ZD0 of a differential transmission path connected to the load impedances Z1 and Z2, OUTP, and OUTN. Since the final output stage of the output driver circuit 100i illustrated in FIG. 11 has a differential common-source structure, voltage swing of OUTP is in the anti-phase of IN1N and voltage swing of OUTN is in the anti-phase of IN1P.

A driver circuit of back gate terminals NBGN and NBGP of the final output stage transistors N1 and N2 each formed with the NMOS is configured with a differential pair formed of PMOS transistors P1 and P2, a current source formed of an active element or an impedance E2 formed of a passive element, and load impedances Z7 and Z8. Source terminals of the transistors P1 and P2 are short-circuited to a high-potential side power source VDD by the current source or the impedance E2. Drain terminals of the differential pair are connected to back gate terminals NBGP and NBGN and are short-circuited to a low-potential side power source VSS by the load impedances Z7 and Z8. Current supplied to the differential pair from the current source or the impedance E2 is switched by a potential difference between IN3P and IN3N, and then supplied to the load impedances Z7 and Z8. Since the driver circuit of the back gate terminals NBGN and NBGP of the output driver circuit 100i illustrated in FIG. 11 has a differential common-source structure, voltage swing of the back gate terminal NBGP is in the anti-phase of IN3N, and voltage swing of the back gate terminal NBGN is in the anti-phase of IN3P.

The output driver circuit 100i illustrated in FIG. 11 operates such that the voltage swing of the back gate terminals NBGN and NBGP of the two final output stage NMOS transistors is in the same phase as the output terminals OUTP and OUTN, respectively, to which the respective drain terminals are connected. Accordingly, by setting voltage-swing values of the back gate terminals NBGP and NBGN to appropriate values, the charge/discharge to parasitic capacitances CP1 and CP2 can be suppressed.

### Specific Configuration Example (8)

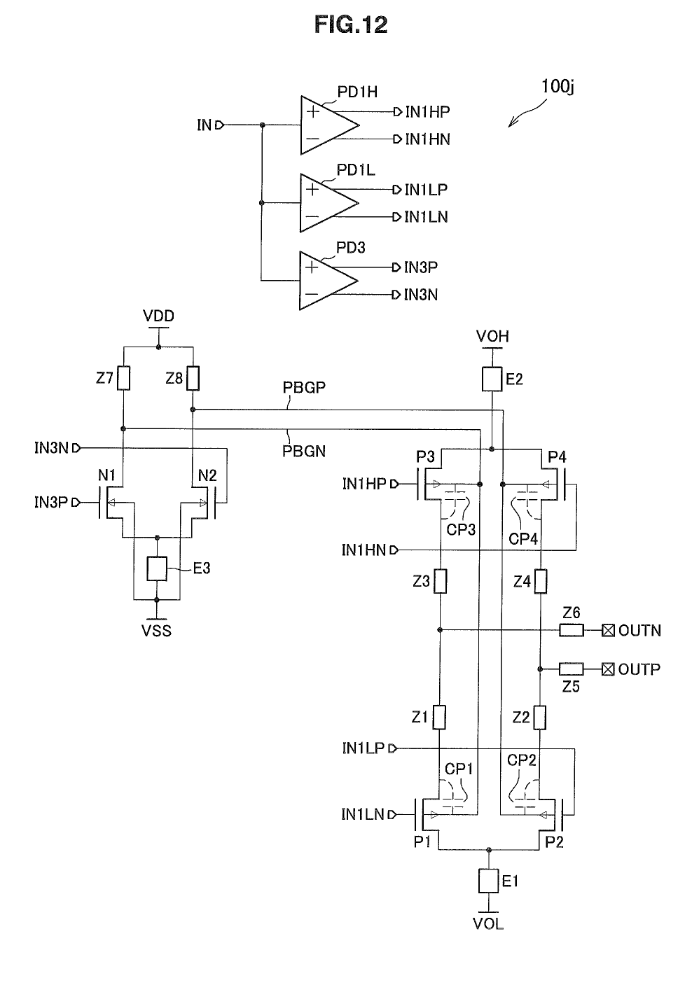

FIG. 12 is an explanatory view illustrating a specific configuration example of an output driver circuit according to an embodiment of the present disclosure. FIG. 12 illustrates an output driver circuit 100j. The output driver circuit 100j illustrated in FIG. 12 is a push-pull differential output driver circuit in which a final output stage transistor is formed with four PMOSs.

An input signal from IN illustrated in FIG. 12 is buffered in the output driver circuit 100j and is output from OUTP and OUTN. The input signal from IN is converted to IN1HP and IN1HN in a pre-driver PD1H, to IN1LP and IN1LN in a pre-driver PD1L, and to IN3P and IN3N in a pre-driver PD3. An unillustrated differential characteristic impedance ZD0 is connected between OUTP and OUTN.

Impedances Z1, Z2, Z3, Z4, Z5, and Z6 illustrated in FIG. 12 may be added in order to adjust the impedance, but are not necessarily provided. Therefore, the impedances Z1, Z2, Z3, Z4, Z5, and Z6 are regarded as zero and negligible in the following description.

A final output stage of the output driver circuit 100j is formed with a differential pair formed of PMOS transistors P3 and P4, PMOS transistors P1 and P2, and a current source formed of an active element or impedances E1 and E2 each formed of a passive element. Source terminals of the transistors P3 and P4 are short-circuited to a high-potential side power source VOH for the final output stage by the current source or the impedance E2, and drain terminals thereof are connected to OUTN and OUTP, respectively. Source terminals of the transistors P1 and P2 are connected to OUTN and OUTP, respectively, and drain terminals thereof are short-circuited to each other and short-circuited to a low-potential side power source VOL for the final output stage by the current source or the impedance E1. Since the final output stage of the output driver circuit 100j illustrated in FIG. 12 has a differential push-pull structure, voltage swing of OUTP is in the anti-phase of IN1HN and in the same phase as IN1LP, and voltage swing of OUTN is in the anti-phase of IN1HP and in the same phase as IN1LN.

A driver circuit of back gate terminals PBGN and PBGP of the final output stage transistors P1, P3, P2, and P4 each formed with the PMOS is configured with a differential pair formed of NMOS transistors N1 and N2, a current source formed of an active element or an impedance E3 formed of a passive element, and load impedances Z7 and Z8. Source terminals of the transistors N1 and N2 are short-circuited to a low-potential side power source VSS by the current source or the impedance E3. Drain terminals of the differential pair formed of the transistors N1 and N2 are connected to back gate terminals PBGN and PBGP and are short-circuited to a high-potential side power source VDD by the load impedances Z7 and Z8. Current supplied to the differential pair formed of the transistors N1 and N2 from the current source or the impedance E3 is switched by a potential difference between IN3P and IN3N, and then supplied to the load impedances Z7 and Z8. Since the driver circuit of the back gate terminals PBGN and PBGP of the output driver circuit 100j illustrated in FIG. 12 has a differential common-source structure, voltage swing of the back gate terminal PBGP is in the anti-phase of IN3N, and voltage swing of the back gate terminal PBGN is in the anti-phase of IN3P.

The output driver circuit 100j illustrated in FIG. 12 operates such that the voltage swing of the back gate terminals PBGN and PBGP of the four final output stage PMOS transistors is in the same phase as the output terminals OUTP and OUTN to which the respective source terminals or drain terminals are connected, respectively. Accordingly, by setting voltage-swing values of the back gate terminals PBGN and PBGP to appropriate values, the charge/discharge to parasitic capacitances CP1, CP2, CP3, and CP4 can be suppressed.

### Specific Configuration Example (9)

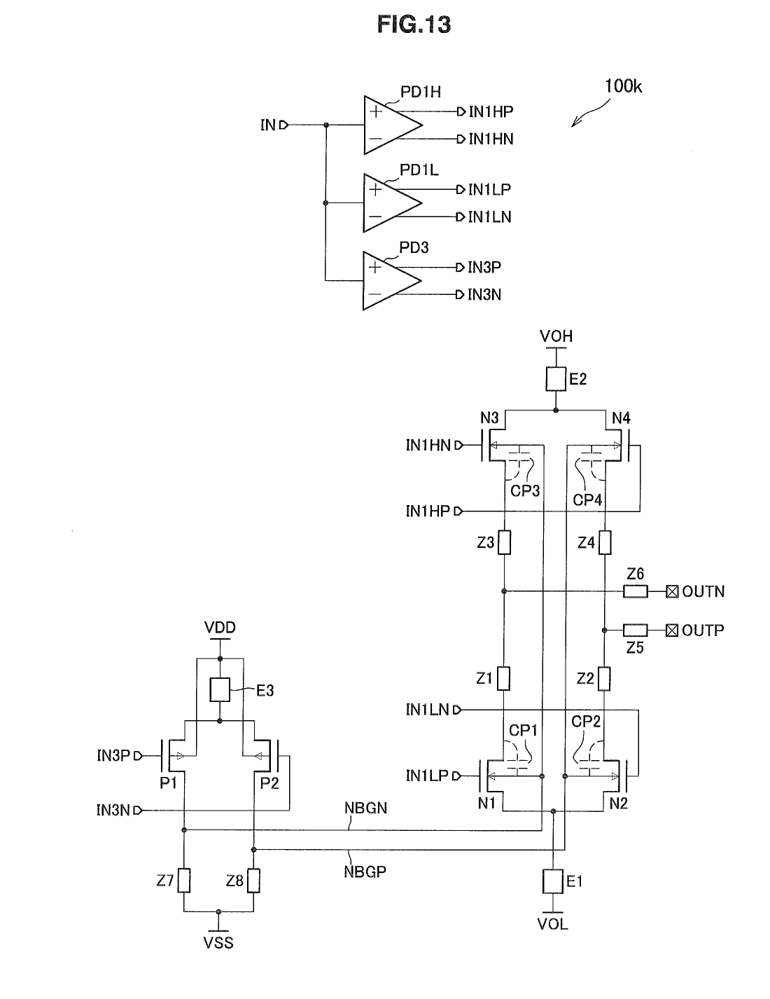

FIG. 13 is an explanatory view illustrating a specific configuration example of an output driver circuit according to an embodiment of the present disclosure. FIG. 13 illustrates an output driver circuit 100k. The output driver circuit 100k illustrated in FIG. 13 is a push-pull differential output driver circuit in which a final output stage transistor is formed with four NMOSs.

An input signal from IN illustrated in FIG. 13 is buffered in the output driver circuit 100k and is output from OUTP and OUTN. The input signal from IN is converted to IN1HP and IN1HN in a pre-driver PD1H, to IN1LP and IN1LN in a pre-driver PD1L, and to IN3P and IN3N in a pre-driver PD3. An unillustrated differential characteristic impedance ZD0 is connected between OUTP and OUTN.

Impedances Z1, Z2, Z3, Z4, Z5, and Z6 illustrated in FIG. 13 may be added in order to adjust the impedance, but are not necessarily provided. Therefore, the impedances Z1, Z2, Z3, Z4, Z5, and Z6 are regarded as zero and negligible in the following description.

A final output stage of the output driver circuit 100k is formed with a differential pair formed of NMOS transistors N1 and N2, NMOS transistors N3 and N4, and a current source formed of an active element or impedances E1 and E2 each formed of a passive element. Source terminals of the transistors N1 and N2 are short-circuited to a low-potential side power source VOL for the final output stage by the current source or the impedance E1, and drain terminals thereof are connected to OUTN and OUTP, respectively. Source terminals of the transistors N3 and N4 are connected to OUTN and OUTP, respectively, and drain terminals thereof are short-circuited to each other and short-circuited to a high-potential side power source VOH for the final output stage by the current source or the impedance E2. Since the final output stage of the output driver circuit 100k illustrated in FIG. 13 has a differential push-pull structure, voltage swing of OUTP is in the anti-phase of IN1LN and in the same phase as IN1HP, and voltage swing of OUTN is in the anti-phase of IN1LP and in the same phase as IN1HN.

A driver circuit of back gate terminals NBGN and NBGP of the final output stage transistors N1, N3, N2, and N4 each formed with the NMOS is configured with a differential pair formed of PMOS transistors P1 and P2, a current source formed of an active element or an impedance E3 formed of a passive element, and load impedances Z7 and Z8. Source terminals of the transistors P1 and P2 are short-circuited to a high-potential side power source VDD by the current source or the impedance E3. Drain terminals of the differential pair are connected to back gate terminals NBGN and NBGP and are short-circuited to a low-potential side power source VSS by the load impedances Z7 and Z8. Current supplied to the differential pair from the current source or the impedance E3 is switched by a potential difference between IN3P and IN3N, and then supplied to the load impedances Z7 and Z8. Since the driver circuit of the back gate terminals NBGN and NBGP of the output driver circuit 100k illustrated in FIG. 13 has a differential common-source structure, voltage swing of the back gate terminal NBGP is in the anti-phase of IN3N, and voltage swing of the back gate terminal NBGN is in the anti-phase of IN3P.

The output driver circuit 100k illustrated in FIG. 13 operates such that the voltage swing of the back gate terminals NBGN and NBGP of the four final output stage NMOS transistors is in the same phase as the output terminals OUTP and OUTN to which the respective source terminals or drain terminals are connected, respectively. Accordingly, by setting voltage-swing values of the back gate terminals NBGP and NBGN to appropriate values, the charge/discharge to parasitic capacitances CP1, CP2, CP3, and CP4 can be suppressed.

### Specific Configuration Example (10)

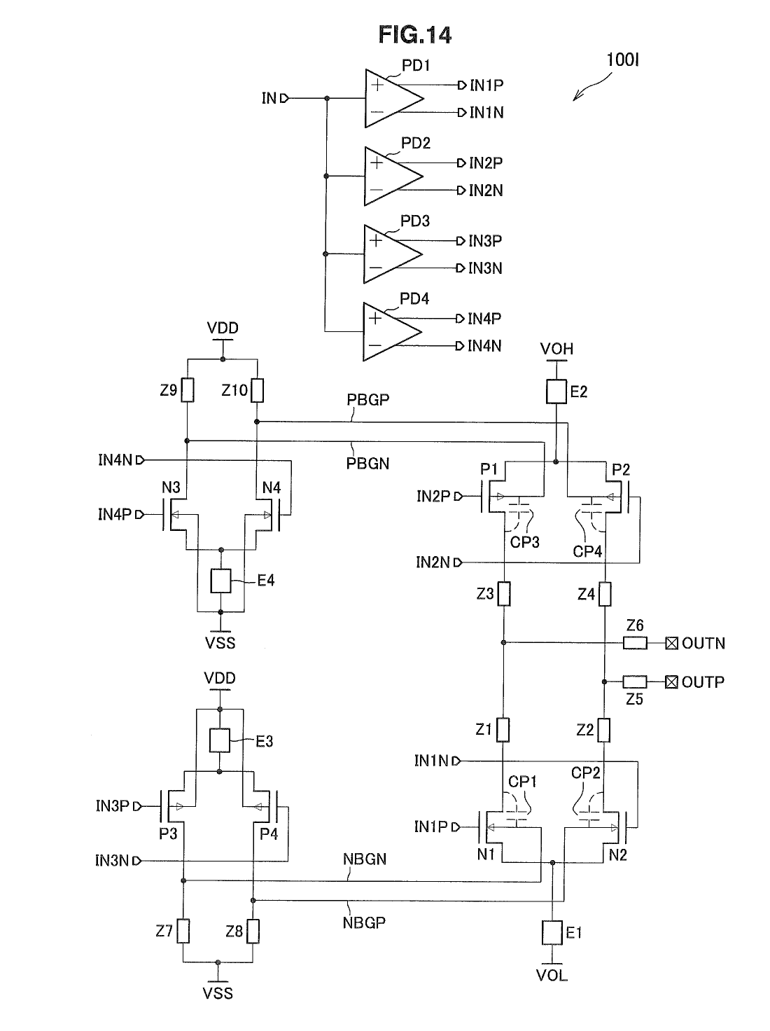

FIG. 14 is an explanatory view illustrating a specific configuration example of an output driver circuit according to an embodiment of the present disclosure. FIG. 14 illustrates an output driver circuit 100l. The output driver circuit 100l illustrated in FIG. 14 is an inverter differential output driver circuit in which a final output stage transistor is formed with two NMOS transistors and two PMOS transistors.

An input signal from IN illustrated in FIG. 14 is buffered in the output driver circuit 100l and is output from OUTP and OUTN. The input signal from IN is converted to IN1P and IN1N in a pre-driver PD1, to IN2P and IN2N in a pre-driver PD2, to IN3P and IN3N in a pre-driver PD3, and to IN4P and IN4N in a pre-driver PD4. An unillustrated differential characteristic impedance ZD0 is connected between OUTP and OUTN.

Impedances Z1, Z2, Z3, Z4, Z5, and Z6 illustrated in FIG. 14 may be added in order to adjust the impedance, but are not necessarily provided. Therefore, the impedances Z1, Z2, Z3, Z4, Z5, and Z6 are regarded as zero and negligible in the following description.

A final output stage of the output driver circuit 100l is formed with a differential pair formed of PMOS transistors P1 and P2, a differential pair formed of NMOS transistors N1 and N2, and a current source formed of an active element or impedances E1 and E2 each formed of a passive element. Source terminals of the transistors P1 and P2 are short-circuited to a high-potential side power source VOH for the final output stage by the current source or the impedance E2, and drain terminals thereof are connected to OUTN and OUTP. Source terminals of the transistors N1 and N2 are short-circuited to a low-potential side power source VOL for the final output stage by the current source or the impedance E1, and drain terminals thereof are connected to OUTN and OUTP. Since the final output stage of the output driver circuit 100l illustrated in FIG. 14 has a differential inverter structure, voltage swing of OUTP is in the anti-phase of IN1N and IN2N, and voltage swing of OUTN is in the anti-phase of IN1P and IN2P.

A driver circuit of back gate terminals PBGP and PBGN of final output stage transistors P1 and P2 each formed with the PMOS is formed with a differential pair formed of transistors N3 and N4 each formed with the NMOS, a current source formed of an active element or an impedance E4 formed of a passive element, and load impedances Z9 and Z10. Source terminals of the transistors N3 and N4 are short-circuited to a low-potential side power source VSS by the current source or the impedance E4. Drain terminals of the differential pair formed of the transistors N3 and N4 are connected to the back gate terminals PBGN and PBGP and are short-circuited to a high-potential side power source VDD by the load impedances Z9 and Z10. Current supplied to the differential pair formed of the transistors N3 and N4 from the current source or the impedance E4 is switched by a potential difference between IN4P and IN4N and then supplied to the load impedances Z9 and Z10. Since the driver circuit of the back gate terminals PBGP and PBGN of the output driver circuit 100l illustrated in FIG. 14 has a differential common-source structure, voltage swing of the back gate terminal PBGP is in the anti-phase of IN4N, and voltage swing of the back gate terminal PBGN is in the anti-phase of IN4P.

A driver circuit of back gate terminals NBGP and NBGN of the final output stage transistors N1 and N2 each formed with the NMOS is configured with a differential pair formed of transistors P3 and P4 each formed with the PMOS, a current source formed of an active element or an impedance E3 formed of a passive element, and load impedances Z7 and Z8. Source terminals of the transistors P3 and P4 are short-circuited to a high-potential side power source VDD by the current source or the impedance E3. Drain terminals of the differential pair formed of the transistors P3 and P4 are connected to back gate terminals NBGN and NBGP and are short-circuited to a low-potential side power source VSS by the load impedances Z7 and Z8. Current supplied to the differential pair formed of the transistors P3 and P4 from the current source or the impedance E3 is switched by a potential difference between IN3P and IN3N, and then supplied to the load impedances Z7 and Z8. Since the driver circuit of the back gate terminals NBGP and NBGN of the output driver circuit 100l illustrated in FIG. 14 has a differential common-source structure, voltage swing of the back gate terminal NBGP is in the anti-phase of IN3N, and voltage swing of the back gate terminal NBGN is in the anti-phase of IN3P.

The output driver circuit 100l illustrated in FIG. 14 operates such that the voltage swing of the back gate terminals of the two final output stage PMOS transistors and the two final output stage NMOS transistors is in the same phase as the output terminals OUTP and OUTN, respectively, to which the respective drain terminals are connected. Accordingly, by setting voltage-swing values of the back gate terminals PBGP and PBGN and the back gate terminals NBGP and NBGN to appropriate values, the charge/discharge to parasitic capacitances CP1, CP2, CP3, and CP4 can be suppressed.

### Effects of Embodiment of Present Disclosure

As described above, by suppressing charge/discharge of a parasitic capacitance of a final output stage transistor, an output driver circuit according to an embodiment of the present disclosure can prevent a decrease in slew rate. Further, by preventing the decrease in slew rate, the output driver circuit according to an embodiment of the present disclosure can output signals having a high-speed data rate. In particular, the output driver circuit according to an embodiment of the present disclosure is suitable for transmitting digital data having a high-speed transmission rate such as a data rate over 1 Gbps.

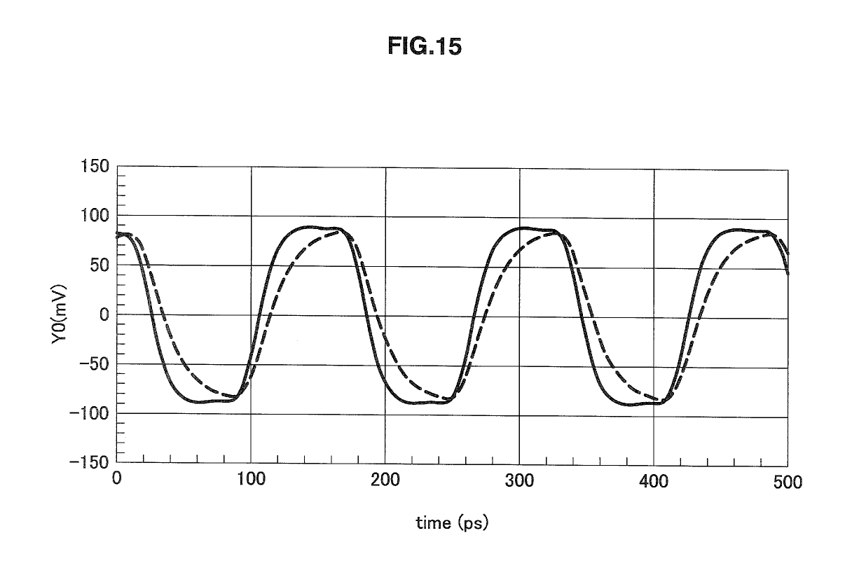

Here, effects of the output driver circuit according to an embodiment of the present disclosure will be described. FIG. 15 is an explanatory view in which effects of the output driver circuit according to an embodiment of the present disclosure are shown as a graph. In the graph shown in FIG. 15, a broken line represents an output waveform in a case where charge/discharge of a parasitic capacitance of a final output stage transistor is not suppressed, and a solid line represents an output waveform in a case where charge/discharge of a parasitic capacitance of a final output stage transistor is suppressed by the output driver circuit (e.g., the output driver circuit 100h illustrated in FIG. 10) according to an embodiment of the present disclosure.

As shown in FIG. 15, in a case where the charge/discharge of a parasitic capacitance of the final output stage transistor is not suppressed, the rise and fall of the waveform are blunt. Such a blunt rise and fall in the waveform may be an obstacle to make higher speed data rate.

Meanwhile, as shown in FIG. 15, in a case where the charge/discharge of a parasitic capacitance of the final output stage transistor is suppressed, the rise and fall of the waveform are sharper than in a case where the charge/discharge of a parasitic capacitance of the final output stage is not suppressed. Such a sharp rise and fall in the waveform enables the output driver circuit according to an embodiment of the present disclosure to prevent a decrease in slew rate and to output signals having a high-speed data rate such as a data rate over 1 Gbps.

Note that a high-potential side power source VOH for the final output stage in the above-described configuration examples may be provided specially for the final output stage of each output driver circuit or may be short-circuited to a high-potential side power source VDD. Further, a low-potential side power source VOL for the final output stage in the above-described configuration examples may be provided specially for the final output stage of each output driver circuit or may be short-circuited to a low-potential side power source VSS.

### Configuration Example of Imaging Device Including Output Driver Circuit

The configuration of the output driver circuit that can prevent a decrease in slew rate and output signals having a high-speed data rate has been described above. Subsequently, as an example of a device including such an output driver circuit, a configuration example of an imaging device including the output driver circuit will be described.

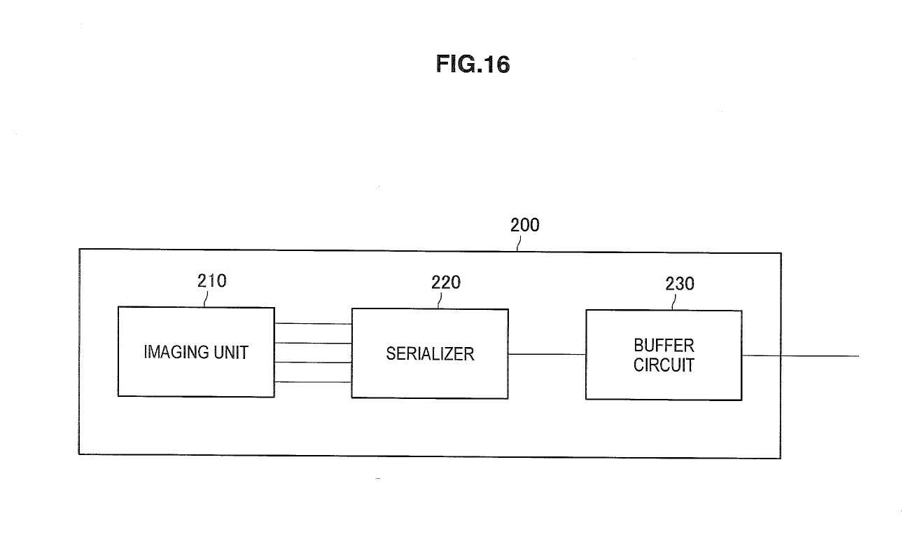

FIG. 16 is an explanatory view illustrating a functional configuration example of an imaging device including an output driver circuit according to an embodiment of the present disclosure. An imaging device 200 illustrated in FIG. 16 includes an imaging unit 210, a serializer 220, and a buffer circuit 230.

The imaging unit 210 is a camera module including imaging elements such as a camera lens, a charge coupled device (CCD), and a complementary metal oxide semiconductor (CMOS), in order to obtain a still image or a moving image. Signals output from the imaging unit 210 are transmitted to the serializer 220. In this embodiment, signals output from the imaging unit 210 are transmitted to the serializer 220 in parallel.

The serializer 220 converts signals output from the imaging unit 210 to serial data and outputs the serial data to the buffer circuit 230.

The buffer circuit 230 has any of the configurations of the above-described output driver circuits 100a to 100l. The buffer circuit 230 buffers signals output from the serializer 220 and outputs the signals to the outside of the imaging device 200.

With the configuration illustrated in FIG. 16, the imaging device 200 can transmit the moving image shot by the imaging unit 210 at high speed. The imaging device 200 illustrated in FIG. 16 can achieve acceleration in transmission rate expected in the medical equipment field in accordance with higher resolution images and 3D images for surgical microscopes for example. In particular, in the electronic endoscopy field, high-speed digital signals are required to be transmitted with as few signal lines as possible; therefore, the imaging device 200 that can further accelerate a transmission rate per signal line can meet such a demand in the electronic endoscopy field.

Other than in the medical equipment field, any of the configurations of the above-described output driver circuits 100a to 100l can also achieve acceleration in transmission rate in accordance with higher resolution images and 3D images. For example, in an image transmitting system in which no long delay is permitted from when an image is transmitted to when a receiver displays the image, an apparatus that transmits the image may include any of the configurations of the above-described output driver circuits 100a to 100l.

### 3. CONCLUSION

As described above, according to an embodiment of the present disclosure, by suppressing charge/discharge of a parasitic capacitance of a final output stage transistor, it is possible to provide an output driver circuit that can prevent a decrease in slew rate. Further, by preventing the decrease in slew rate, the output driver circuit according to an embodiment of the present disclosure can output signals having a high-speed data rate such as a data rate over 1 Gbps

Further, according to an embodiment of the present disclosure, it is possible to provide an imaging device including the above-described output driver circuit. Since the imaging device according to an embodiment of the present disclosure includes the above-described output driver circuit, a moving image can be transmitted at high speed with as few signal lines as possible.

Although preferred embodiments of the present disclosure are described in detail with reference to the accompanying drawings, the technical scope of the present disclosure is not limited thereto. It should be understood by those skilled in the art that various modifications, combinations, sub-combinations and alterations may occur depending on design requirements and other factors insofar as they are within the scope of the appended claims or the equivalents thereof.

Additionally, the present technology may also be configured as below.

(1)
A semiconductor integrated circuit including:

at least one MOS transistor a source or drain of which is connected an output terminal; and

a driver circuit configured to drive a back gate or a well of the MOS transistor in a manner that voltage swing is in a same phase as the output terminal.

(2)
The semiconductor integrated circuit according to (1),

wherein the at least one MOS transistor is a PMOS transistor fabricated through a twin well or triple well CMOS process using a p-type wafer, and

wherein the driver circuit drives an n-type well forming a back gate or a well of the PMOS transistor, and drives the back gate or the well of the PMOS transistor in a manner that voltage swing is in a same phase as the output terminal

(3)
The semiconductor integrated circuit according to (2),

wherein a source terminal of the PMOS transistor is short-circuited to a high-potential side power source line via a predetermined impedance and a drain terminal of the PMOS transistor is connected to the output terminal, and

wherein the driver circuit drives the back gate or the well of the PMOS transistor in a manner that voltage swing is in an anti-phase of a gate electrode of the PMOS transistor.

(4)
The semiconductor integrated circuit according to (2),

wherein a first PMOS transistor and a second PMOS transistor are connected in series, the first PMOS transistor being disposed between the output terminal and a low-potential side power source line, the second PMOS transistor being disposed between the output terminal and a high-potential side power source line, a source terminal of the first PMOS transistor is connected to the output terminal, and a source terminal of the second PMOS transistor is short-circuited to the high-potential side power source line via a predetermined impedance and a drain terminal of the second PMOS transistor is connected to the output terminal, and

wherein the driver circuit drives a back gate or a well of the first PMOS transistor in a manner that voltage swing is in a same phase as a gate electrode of the first PMOS transistor and drives a back gate or a well of the second PMOS transistor in a manner that voltage swing is in an anti-phase of a gate electrode of the second PMOS transistor.

(5)
The semiconductor integrated circuit according to (2),

wherein two PMOS transistors are connected in parallel, and source terminals of the two PMOS transistors are short-circuited to each other and drain terminals of the two PMOS transistors are connected to respective terminals of the output terminal having a differential configuration, and

wherein the driver circuit drives back gates or wells of the two PMOS transistors in a manner that voltage swing is in an anti-phase of respective gate electrodes of the PMOS transistors.

(6)
The semiconductor integrated circuit according to (2),

wherein a set of a first PMOS transistor and a second PMOS transistor connected in series and a set of a first PMOS transistor and a second PMOS transistor connected in series are connected in parallel, the first PMOS transistors each being disposed between the output terminal having a differential configuration and a low-potential side power source line, the second PMOS transistors each being disposed between the output terminal having a differential configuration and a high-potential side power source line, source terminals of the first PMOS transistors are connected to the output terminal having a differential configuration, and source terminals of the second PMOS transistors are short-circuited to the high-potential side power source line via a predetermined impedance and drain terminals of the second PMOS transistors are connected to the output terminal having a differential configuration, and

wherein the driver circuit drives back gates or wells of the first PMOS transistors in a manner that voltage swing is in a same phase as gate electrodes of the first PMOS transistors and drives back gates or wells of the second PMOS transistors in a manner that voltage swing is in an anti-phase of gate electrodes of the second PMOS transistors.

(7)
The semiconductor integrated circuit according to (1),

wherein the at least one MOS transistor is an NMOS transistor fabricated through a triple well CMOS process using a p-type wafer, and

wherein the driver circuit drives a p-type well forming a back gate or a well of the NMOS transistor, and drives the back gate or the well of the NMOS transistor in a manner that voltage swing is in a same phase as the output terminal

(8)
The semiconductor integrated circuit according to (7),

wherein a source terminal of the NMOS transistor is short-circuited to a low-potential side power source line via a predetermined impedance and a drain terminal of the NMOS transistor is connected to the output terminal, and

wherein the driver circuit drives the back gate or the well of the NMOS transistor in a manner that voltage swing is in an anti-phase of a gate electrode of the NMOS transistor.

(9)
The semiconductor integrated circuit according to (7),

wherein a first NMOS transistor and a second NMOS transistor are connected in series, the first NMOS transistor being disposed between the output terminal and a high-potential side power source line, the second NMOS transistor being disposed between the output terminal and a low-potential side power source line, a source terminal of the first NMOS transistor is connected to the output terminal, and a source terminal of the second NMOS transistor is short-circuited to the low-potential side power source line via a predetermined impedance and a drain terminal of the second NMOS transistor is connected to the output terminal, and

wherein the driver circuit drives a back gate or a well of the first NMOS transistor in a manner that voltage swing is in a same phase as a gate electrode of the first NMOS transistor and drives a back gate or a well of the second NMOS transistor in a manner that voltage swing is in an anti-phase of a gate electrode of the second NMOS transistor.

(10)
The semiconductor integrated circuit according to (7),

wherein two NMOS transistors are connected in parallel, and source terminals of the two NMOS transistors are short-circuited to each other and drain terminals of the two NMOS transistors are connected to respective terminals of the output terminal having a differential configuration, and

wherein the driver circuit drives back gates or wells of the two NMOS transistors in a manner that voltage swing is in an anti-phase of respective gate electrodes of the NMOS transistors.

(11)
The semiconductor integrated circuit according to (7),

wherein a set of a first NMOS transistor and a second NMOS transistor connected in series and a set of a first NMOS transistor and a second NMOS transistor connected in series are connected in parallel, the first NMOS transistors each being disposed between the output terminal having a differential configuration and a high-potential side power source line, the second NMOS transistors each being disposed between the output terminal having a differential configuration and a low-potential side power source line, source terminals of the first NMOS transistors are connected to the output terminal having a differential configuration, and source terminals of the second NMOS transistors are short-circuited to the low-potential side power source line via a predetermined impedance and drain terminals of the second NMOS transistors are connected to the output terminal having a differential configuration, and

wherein the driver circuit drives back gates or wells of the first NMOS transistors in a manner that voltage swing is in a same phase as gate electrodes of the first NMOS transistors and drives back gates or wells of the second NMOS transistors in a manner that voltage swing is in an anti-phase of gate electrodes of the second NMOS transistors.

(12)
The semiconductor integrated circuit according to (1),

wherein the MOS transistor is a PMOS transistor and an NMOS transistor each fabricated through a triple well CMOS process using a p-type wafer,

wherein the driver circuit drives an n-type well forming a back gate or a well of the PMOS transistor and a p-type well forming a back gate or a well of the NMOS transistor, and drives the back gates or the wells in a manner that voltage swing is in a same phase as the output terminal

(13)
The semiconductor integrated circuit according to (12),

wherein the PMOS transistor and the NMOS transistor are connected in series, the PMOS transistor being disposed between the output terminal and a high-potential side power source line, the NMOS transistor being disposed between the output terminal and a low-potential side power source line, a source terminal of the PMOS transistor is short-circuited to the high-potential side power source line via a predetermined impedance and a drain terminal of the PMOS transistor is connected to the output terminal, and a source terminal of the NMOS transistor which is short-circuited to the low-potential side power source line via a predetermined impedance and a drain terminal of the NMOS transistor is connected to the output terminal, and

wherein the driver circuit independently drives the back gate of the PMOS transistor and the back gate of the NMOS transistor in a manner that voltage swing is in an anti-phase of a gate electrode of the PMOS transistor or the NMOS transistor.

(14)
The semiconductor integrated circuit according to (12),

wherein a set of a PMOS transistor and an NMOS transistor connected in series and a set of a PMOS transistor and an NMOS transistor connected in series are connected in parallel, the PMOS transistors each being disposed between the output terminal having a differential configuration and a high-potential side power source line, the NMOS transistors each being disposed between the output terminal having a differential configuration and a low-potential side power source line, source terminals of the PMOS transistors are short-circuited to the high-potential side power source line via a predetermined impedance and drain terminals of the PMOS transistors are connected to the output terminal having a differential configuration, and source terminals of the NMOS transistors are short-circuited to the low-potential side power source line via a predetermined impedance and drain terminals of the NMOS transistors are connected to the output terminal having a differential configuration, and

wherein the driver circuit independently drives back gates of the PMOS transistors and back gates of the NMOS transistors in a manner that voltage swing is in an anti-phase of gate electrodes of the PMOS transistors or the NMOS transistors.

(15)
An imaging device including:

the semiconductor integrated circuit according to any one of (1) to (14).

What is claimed is:

1. A semiconductor integrated circuit comprising:
at least one MOS transistor a source or drain of which is connected an output terminal; and
a driver circuit configured to drive a back gate or a well of the MOS transistor in a manner that voltage swing is in a same phase as the output terminal.

2. The semiconductor integrated circuit according to claim 1,
wherein the at least one MOS transistor is a PMOS transistor fabricated through a twin well or triple well CMOS process using a p-type wafer, and
wherein the driver circuit drives an n-type well forming a back gate or a well of the PMOS transistor, and drives the back gate or the well of the PMOS transistor in a manner that voltage swing is in a same phase as the output terminal.

3. The semiconductor integrated circuit according to claim 2,
wherein a source terminal of the PMOS transistor is short-circuited to a high-potential side power source line via a predetermined impedance and a drain terminal of the PMOS transistor is connected to the output terminal, and
wherein the driver circuit drives the back gate or the well of the PMOS transistor in a manner that voltage swing is in an anti-phase of a gate electrode of the PMOS transistor.

4. The semiconductor integrated circuit according to claim 2,
wherein a first PMOS transistor and a second PMOS transistor are connected in series, the first PMOS transistor being disposed between the output terminal and a low-potential side power source line, the second PMOS transistor being disposed between the output terminal and a high-potential side power source line, a source terminal of the first PMOS transistor is connected to the output terminal, and a source terminal of the second PMOS transistor is short-circuited to the high-potential side power source line via a predetermined impedance and a drain terminal of the second PMOS transistor is connected to the output terminal, and
wherein the driver circuit drives a back gate or a well of the first PMOS transistor in a manner that voltage swing is in a same phase as a gate electrode of the first PMOS transistor and drives a back gate or a well of the second PMOS transistor in a manner that voltage swing is in an anti-phase of a gate electrode of the second PMOS transistor.

5. The semiconductor integrated circuit according to claim 2,
wherein two PMOS transistors are connected in parallel, and source terminals of the two PMOS transistors are short-circuited to each other and drain terminals of the two PMOS transistors are connected to respective terminals of the output terminal having a differential configuration, and
wherein the driver circuit drives back gates or wells of the two PMOS transistors in a manner that voltage swing is in an anti-phase of respective gate electrodes of the PMOS transistors.

6. The semiconductor integrated circuit according to claim 2,
wherein a set of a first PMOS transistor and a second PMOS transistor connected in series and a set of a first PMOS transistor and a second PMOS transistor connected in series are connected in parallel, the first PMOS transistors each being disposed between the output terminal having a differential configuration and a low-potential side power source line, the second PMOS transistors each being disposed between the output terminal having a differential configuration and a high-potential side power source line, source terminals of the first PMOS transistors are connected to the output terminal having a differential configuration, and source terminals of the second PMOS transistors are short-circuited to the high-potential side power source line via a predetermined impedance and drain terminals of the second PMOS transistors are connected to the output terminal having a differential configuration, and
wherein the driver circuit drives back gates or wells of the first PMOS transistors in a manner that voltage swing is in a same phase as gate electrodes of the first PMOS transistors and drives back gates or wells of the second PMOS transistors in a manner that voltage swing is in an anti-phase of gate electrodes of the second PMOS transistors.

7. The semiconductor integrated circuit according to claim 1,
wherein the at least one MOS transistor is an NMOS transistor fabricated through a triple well CMOS process using a p-type wafer, and
wherein the driver circuit drives a p-type well forming a back gate or a well of the NMOS transistor, and drives the back gate or the well of the NMOS transistor in a manner that voltage swing is in a same phase as the output terminal.

8. The semiconductor integrated circuit according to claim 7,
wherein a source terminal of the NMOS transistor is short-circuited to a low-potential side power source line via a predetermined impedance and a drain terminal of the NMOS transistor is connected to the output terminal, and
wherein the driver circuit drives the back gate or the well of the NMOS transistor in a manner that voltage swing is in an anti-phase of a gate electrode of the NMOS transistor.

9. The semiconductor integrated circuit according to claim 7,
wherein a first NMOS transistor and a second NMOS transistor are connected in series, the first NMOS transistor being disposed between the output terminal and a high-potential side power source line, the second NMOS transistor being disposed between the output terminal and a low-potential side power source line, a source terminal of the first NMOS transistor is connected to the output terminal, and a source terminal of the second NMOS transistor is short-circuited to the low-potential side power source line via a predetermined impedance and a drain terminal of the second NMOS transistor is connected to the output terminal, and
wherein the driver circuit drives a back gate or a well of the first NMOS transistor in a manner that voltage swing is in a same phase as a gate electrode of the first NMOS transistor and drives a back gate or a well of the second NMOS transistor in a manner that voltage swing is in an anti-phase of a gate electrode of the second NMOS transistor.

10. The semiconductor integrated circuit according to claim 7,
wherein two NMOS transistors are connected in parallel, and source terminals of the two NMOS transistors are short-circuited to each other and drain terminals of the two NMOS transistors are connected to respective terminals of the output terminal having a differential configuration, and
wherein the driver circuit drives back gates or wells of the two NMOS transistors in a manner that voltage swing is in an anti-phase of respective gate electrodes of the NMOS transistors.

11. The semiconductor integrated circuit according to claim 7,
wherein a set of a first NMOS transistor and a second NMOS transistor connected in series and a set of a first NMOS transistor and a second NMOS transistor connected in series are connected in parallel, the first NMOS transistors each being disposed between the output terminal having a differential configuration and a high-potential side power source line, the second NMOS transistors each being disposed between the output terminal having a differential configuration and a low-potential side power source line, source terminals of the first NMOS transistors are connected to the output terminal having a differential configuration, and source terminals of the second NMOS transistors are short-circuited to the low-potential side power source line via a predetermined impedance and drain terminals of the second NMOS transistors are connected to the output terminal having a differential configuration, and
wherein the driver circuit drives back gates or wells of the first NMOS transistors in a manner that voltage swing is in a same phase as gate electrodes of the first NMOS transistors and drives back gates or wells of the second NMOS transistors in a manner that voltage swing is in an anti-phase of gate electrodes of the second NMOS transistors.

12. The semiconductor integrated circuit according to claim 1,
wherein the MOS transistor is a PMOS transistor and an NMOS transistor each fabricated through a triple well CMOS process using a p-type wafer,
wherein the driver circuit drives an n-type well forming a back gate or a well of the PMOS transistor and a p-type well forming a back gate or a well of the NMOS transistor, and drives the back gates or the wells in a manner that voltage swing is in a same phase as the output terminal.

13. The semiconductor integrated circuit according to claim 12,
wherein the PMOS transistor and the NMOS transistor are connected in series, the PMOS transistor being disposed between the output terminal and a high-potential side power source line, the NMOS transistor being disposed between the output terminal and a low-potential side power source line, a source terminal of the PMOS transistor is short-circuited to the high-potential side power source line via a predetermined impedance and a drain terminal of the PMOS transistor is connected to the output terminal, and a source terminal of the NMOS transistor which is short-circuited to the low-potential side power source line via a predetermined impedance and a drain terminal of the NMOS transistor is connected to the output terminal, and
wherein the driver circuit independently drives the back gate of the PMOS transistor and the back gate of the NMOS transistor in a manner that voltage swing is in an anti-phase of a gate electrode of the PMOS transistor or the NMOS transistor.

14. The semiconductor integrated circuit according to claim 12,
wherein a set of a PMOS transistor and an NMOS transistor connected in series and a set of a PMOS transistor and an NMOS transistor connected in series are connected in parallel, the PMOS transistors each being disposed between the output terminal having a differential configuration and a high-potential side power source line, the NMOS transistors each being disposed between the output terminal having a differential configuration and a low-potential side power source line, source terminals of the PMOS transistors are short-circuited to the high-potential side power source line via a predetermined impedance and drain terminals of the PMOS transistors are connected to the output terminal having a differential configuration, and source terminals of the NMOS transistors are short-circuited to the low-potential side power source line via a predetermined impedance and drain terminals of the NMOS transistors are connected to the output terminal having a differential configuration, and
wherein the driver circuit independently drives back gates of the PMOS transistors and back gates of the NMOS transistors in a manner that voltage swing is in an anti-phase of gate electrodes of the PMOS transistors or the NMOS transistors.

15. An imaging device comprising:
the semiconductor integrated circuit according to claim 1.
